(19) United States
(12) Patent Application Publication
(10) Pub. No.: US 2025/0045472 A1
(43) Pub. Date: Feb. 6, 2025

(54) DESIGN SPACE WITH INTEGRATED PROMPT SPACE FOR MACHINE LEARNING MODELS

(71) Applicant: AUTODESK, INC., San Francisco, CA (US)

(72) Inventors: George William FITZMAURICE, Toronto (CA); Jo Karel VERMEULEN, East York (CA); Justin Frank MATEJKA, Newmarket (CA)

(21) Appl. No.: 18/748,933

(22) Filed: Jun. 20, 2024

Related U.S. Application Data
(60) Provisional application No. 63/516,666, filed on Jul. 31, 2023.

(51) Int. Cl. G06F 30/12; G06F 30/27

(52) U.S. Cl. CPC G06F 30/12; G06F 30/27

(57) ABSTRACT

In various embodiments, a computer-implemented method for displaying a prompt space, the method comprising displaying a design space comprising one or more design objects, receiving a selection of a current location within the design space, and displaying the prompt space at a placement location within the design space based on the current location. In other embodiments, a computer-implemented method for displaying a prompt history, the method comprising displaying a design space that includes a first design object, displaying a first prompt-history marker within the design space, the first prompt-history marker representing a first prompt history associated with the first design object, and in response to receiving a selection for viewing the first prompt history, displaying the first prompt history in a prompt space within the design space.

### CROSS-REFERENCE TO RELATED APPLICATIONS

This application claims priority benefit of the United States Provisional patent application titled, “GRAPHICAL USER INTERFACE WITH COMBINED CURSOR AND PROMPT FOR ARTIFICIAL INTELLIGENCE MODELS,” filed on Jul. 31, 2023, and having Ser. No. 63/516,666. The subject matter of this related application is hereby incorporated herein by reference.

### BACKGROUND

### Field of the Various Embodiments

The various embodiments relate generally to computer-aided design and artificial intelligence and, more specifically, to a design space with integrated prompt space for machine learning models.

### DESCRIPTION OF THE RELATED ART

Design exploration for three-dimensional (3D) objects generally refers to a phase of a design process during which a designer generates and modifies various 3D objects within an overall 3D design. As is well-understood in practice, manually generating and modifying even a relatively simple 3D object can be very labor-intensive and time-consuming. Because the time allocated for generating a 3D design typically comprising a large number of 3D objects is usually limited, designers typically spend a limited amount of time to generate and modify each 3D object, which oftentimes reduces the overall quality of the final 3D design. Accordingly, various conventional computer-aided design (CAD) applications have been developed that attempt to automate more fully how 3D objects are generated and evaluated.

One approach to automating how CAD applications generate and modify 3D objects within a 3D design involves implementing an artificial intelligence (AI) model, such as a generative machine learning (ML) model, to provide design guidance to the user or automatically synthesize or modify 3D objects in response to prompts provided by the user. A prompt provided to the AI model can be in the form of a query or design problem statement that specifies one or more design characteristics to which a generated or modified 3D object should adhere. The prompt can include any number of quantitative goals, physical objects, physical and functional constraints, and/or mechanical and geometric quantities that guide how the AI model should generate or modify the 3D object. The AI model generates a response to the prompt, such as a natural language text response (displayed in a prompt space) and/or a generated or modified 3D object (displayed in the design space) that satisfies the query or design characteristics specified in the prompt.

Typically a CAD application generates a graphical user interface (GUI) that includes the design space and a separate prompt space for interacting with the AI model. The design space displays the overall 3D design having one or more 3D objects that can include one or more 3D objects that have been automatically generated or modified by the AI model. The prompt space receives the user inputs that are used for generating the prompts to the AI model. The prompt space also displays a prompt history of all prompt interactions with the AI model, including the user inputs for generating the various prompts and the text responses from the AI model to the prompts. In conventional approaches, the prompt space is usually separate from and external to the design space. For example, the prompt space can comprise a panel/window within the GUI that is placed to the left, right, top, or bottom of the design space which also comprises a panel/window within the GUI.

One drawback of the above approach is that, because the prompt space is separate from and external to the design space, the focus of the user oftentimes is diverted from the different 3D objects within the design space when the user interacts with the prompt space. Ideally, the 3D objects within the design space should be the core focus of a user's design work, and distractions from the core design work within the design space can be counterproductive to an efficient design process. Another drawback of the above approach is that, because the prompt space is separate from and external to the design space, when the prompt space displays the history of prompt interactions, a user can have difficulty understanding the context of any given prompt interaction. For example, after a large number of interactions with the AI model, a conventional prompt history usually includes a long list of prompt interactions with no information about which particular 3D objects or locations within the design space are associated with which prompt interactions included in the prompt history. Consequently, the user usually cannot decipher the design process or the prior interactions with the AI model from the prompt history.

As the foregoing illustrates, what is needed in the art are more effective techniques for interacting with AI models when using CAD applications.

### SUMMARY

In various embodiments, a computer-implemented method for displaying a prompt space, the method comprising displaying a design space comprising one or more design objects, receiving a selection of a current location within the design space, and displaying the prompt space at a placement location within the design space based on the current location.

At least one technical advantage of the disclosed techniques relative to the prior art is that the disclosed techniques integrate the prompt space used to interact with an AI model within the design space of a CAD application, which can reduce the amount of distraction users experience when performing design operations in the design space. In this regard, with the disclosed techniques enable the prompt space to be displayed proximate to a currently selected location within the design space, such as a location associated with a currently selected 3D object or an empty location. Spatially placing the prompt space within the design space in association with the user's current focus reduces distraction from design work being performed in the design space and promotes a more efficient design process relative to what users experience with conventional implementations, where the prompt space is separatee from and external to the design space. These technical advantages provide one or more technological advancements over prior art approaches.

In various embodiments, a computer-implemented method for displaying a prompt history, the method comprising displaying a design space that includes a first design object, displaying a first prompt-history marker within the design space, the first prompt-history marker representing a first prompt history associated with the first design object, and in response to receiving a selection for viewing the first prompt history, displaying the first prompt history in a prompt space within the design space.

At least one technical advantage of the disclosed techniques relative to the prior art is that the disclosed techniques record separate and distinct prompt histories for separate and distinct 3D objects and empty locations within the design space. In this regard, in response to a user request to view the prompt history associated with a selected 3D object or empty location within the design space, the prompt history proximate to the selected 3D object or empty location is automatically displayed within the design space. Accordingly, with the disclosed techniques, only the prompt history associated with the selected 3D object or empty location is displayed proximate to the selected 3D object or empty location, which allows the user to more easily review and understand the prior design process and prompt interactions with the AI model relating to the selected 3D object or empty location, relative to conventional implementations. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the design exploration application of FIG. 1, according to various embodiments;

FIG. 3 is a conceptual diagram of one of the prompt-history tables of FIG. 2, according to various embodiments;

FIG. 4 is an exemplar illustration of an initial selection of a design object within the design space of FIG. 2, according to various embodiments;

FIG. 5 is an exemplar illustration of an interaction mode of a prompt space within the design space of FIG. 4, according to various embodiments;

FIG. 6 is an exemplar illustration of an ML response shown in the prompt space of FIG. 5, according to various embodiments;

FIG. 7 is an exemplar illustration of an additional user input shown in the prompt space of FIG. 5, according to various embodiments;

FIG. 8 is an exemplar illustration of an additional ML response shown in the prompt space of FIG. 5, according to various embodiments;

FIG. 9 is an exemplar illustration of a prompt-history marker displayed within the design space of FIG. 4, according to various embodiments;

FIG. 10 is an exemplar illustration of an assembly-level prompt-history marker displayed within the design space of FIG. 2, according to various embodiments;

FIG. 11 is an exemplar illustration of a set of part-level prompt-history markers displayed within the design space of FIG. 10, according to various embodiments;

FIG. 12 is an exemplar illustration of a set of element-level prompt-history markers displayed within the design space of FIG. 10, according to various embodiments;

FIG. 13 is an exemplar illustration of a viewpoint image displayed in the prompt space of FIG. 2, according to various embodiments;

FIG. 14 sets forth a flow diagram of method steps for integrating a prompt space within a design space, according to various embodiments;

FIG. 15 sets forth a flow diagram of method steps for displaying a prompt history within a prompt space, according to various embodiments; and

FIG. 16 depicts one architecture of a system within which the various embodiments may be implemented.

### DETAILED DESCRIPTION

In the following description, numerous specific details are set forth to provide a more thorough understanding of the various embodiments. However, it will be apparent to one skilled in the art that the inventive concepts may be practiced without one or more of these specific details. For explanatory purposes, multiple instances of like objects are symbolized with reference numbers identifying the object and parenthetical numbers(s) identifying the instance where needed.

### System Overview

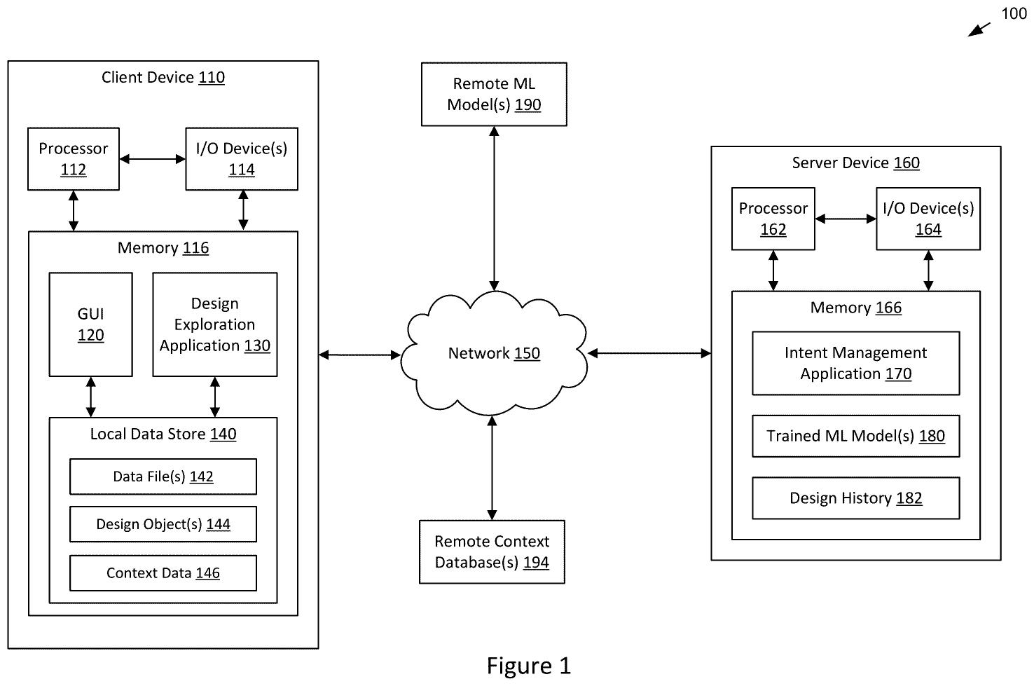

FIG. 1 is a conceptual illustration of a system 100 configured to implement one or more aspects of the various embodiments. As shown, in some embodiments, the system 100 includes, without limitation, a client device 110, a server device 160, one or more remote machine learning (ML) models 190, and one or more remote context databases 194.

The client device 110 includes, without limitation, a processor 112, one or more input/output (I/O) devices 114, and a memory 116. The memory 116 includes, without limitation, a graphical user interface (GUI) 120, a design exploration application 130, and a local data store 140. The local data store 140 includes, without limitation, one or more data files 142, one or more design objects 144, context data 146, and/or one or more snaphot images (not shown). The server device 160 includes, without limitation, a processor 162, one or more I/O devices 164, and a memory 166. The memory 166 includes, without limitation, an intent management application 170, one or more trained ML models 180, and design history 182. In some other embodiments, the system 100 can include any number and/or types of other client devices, server devices, remote ML models, databases, or any combination thereof.

Any number of the components of the system 100 can be distributed across multiple geographic locations or implemented in one or more cloud computing environments (e.g., encapsulated shared resources, software, data) in any combination. In some embodiments, the client device 110 and/or zero or more other client devices (not shown) can be implemented as one or more compute instances in a cloud computing environment, implemented as part of any other distributed computing environment, or implemented in a stand-alone fashion. In various embodiments, the client device 110 can be integrated with any number and/or types of other devices (e.g., one or more other compute instances and/or a display device) into a user device. Some examples of user devices include, without limitation, desktop computers, laptops, smartphones, and tablets.

In general, the client device 110 is configured to implement one or more software applications. For explanatory purposes only, each software application is described as residing in the memory 116 of the client device 110 and executing on the processor 112 of the client device 110. In some embodiments, any number of instances of any number of software applications can reside in the memory 116 and any number of other memories associated with any number of other compute instances and execute on the processor 112 of the client device 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the client device 110 is configured to implement a design exploration application 130 to generate one or more two-dimensional (2D) or 3D designs, such as 2D floorplan designs and/or 3D designs for 3D objects. In some embodiments, the design exploration application 130 causes one or more ML models 180, 190 to synthesize designs for a 3D object based on any number of goals and constraints. The design exploration application 130 then presents the designs as one or more design objects 144 to a user in the context of a design space. In some embodiments, the design objects 144 comprise 2D objects, such as sub-portions of a 2D design, each sub-portion comprising 2D geometries. For example, a 2D design can comprise a building layout and a 2D design object 144 can comprise a particular room of the building layout. Both 3D and 2D designs and design objects 144 can be processed in a similar manner by the embodiments and techniques described herein. In some embodiments, the user can explore and modify the 2D or 3D design objects 144 via the GUI 120.

In various embodiments, the processor 112 can be any instruction execution system, apparatus, or device capable of executing instructions. For example, the processor 112 can comprise general-purpose processors (such as a central processing unit), special-purpose processors (such as a graphics processing unit), application-specific processors, field-programmable gate arrays, or other programmable logic device, discrete gate or transistor logic, discrete hardware components, or any combination of different processing units. In some embodiments, the processor 112 is a programmable processor that executes program instructions to manipulate input data. In some embodiments, the processor 112 can include any number of processing cores, memories, and other modules for facilitating program execution.

The input/output (I/O) devices 114 include devices configured to receive input, including, for example, a keyboard, a mouse, trackball, and so forth. In some embodiments, the I/O devices 114 also includes devices configured to provide output, including, for example, a display device, a speaker, and so forth. For example, an input device can enable a user to control a cursor displayed on an output device for selecting various elements displayed on the output device 114. Additionally or alternatively, the I/O devices 114 may further include devices configured to both receive and provide input and output, respectively, including, for example, a touchscreen, a universal serial bus (USB) port, and so forth.

The memory 116 includes a memory module, or collection of memory modules. In some embodiments, the memory 116 can include a variety of computer-readable media selected for their size, relative performance, or other capabilities: volatile and/or non-volatile media, removable and/or non-removable media, etc. The memory 116 can include cache, random access memory (RAM), storage, etc. The memory 116 can include one or more discrete memory modules, such as dynamic RAM (DRAM) dual inline memory modules (DIMMs). Of course, various memory chips, bandwidths, and form factors may alternately be selected. The memory 116 stores content, such as software applications and data, for use by the processor 112. In some embodiments, a storage (not shown) supplements or replaces the memory 116. The storage can include any number and type of external memories that are accessible to the processor 112 of the client device 110. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 116 generally stores one or more application programs including the design exploration application 130, and data (e.g., the data files 142 and/or the design objects stored in the local data store 140) for processing by the processor 112. In various embodiments, the memory 116 can include non-volatile memory, such as optical drives, magnetic drives, flash drives, or other storage. In some embodiments, separate data stores, such as one or more external data stores connected via the network 150 (“cloud storage”) can supplement the memory 116. In various embodiments, the design exploration application 130 within the memory 116 can be executed by the processor 112 to implement the overall functionality of the client device 110 to coordinate the operation of the system 100 as a whole.

In various embodiments, the memory 116 can include one or more modules for performing various functions or techniques described herein. In some embodiments, one or more of the modules and/or applications included in the memory 116 may be implemented locally on the client device 110, and/or may be implemented via a cloud-based architecture. For example, any of the modules and/or applications included in the memory 116 could be executed on a remote device (e.g., smartphone, a server system, a cloud computing platform, etc.) that communicates with the client device 110 via a network interface or an I/O devices interface.

The design exploration application 130 resides in the memory 116 and executes on the processor 112 of the client device 110. The design exploration application 130 interacts with a user via the GUI 120. In various embodiments, the design exploration application 130 operates as a 2D or 3D design application to generate and modify an overall 2D or 3D design that includes one or more 2D or 3D design objects 144. The design exploration application 130 interacts with a user via the GUI 120 to generate the one or more design objects 144 via direct user input (e.g., one or more tools of the design exploration application 130 are used to generate 3D objects, wireframe geometries, meshes, etc.) or via separate devices (e.g., the trained ML models 180, the remote ML models 190, separate 3D design applications, etc.). When generating the one or more design objects 144 via separate devices, the design exploration application 130 generates (based on user inputs) a prompt that effectively describes design-related intentions using one or more modalities (e.g., text, speech, images, etc.). The design exploration application 130 then causes the one or more of the ML models 180, 190 to operate on the generated prompt to generate a relevant ML response, such as a relevant design object 144. The design exploration application 130 receives the ML response (such as the design object 144) from the one or more ML models 180, 190 and displays the ML response (such as the design object 144) within the GUI 120. The user can select, via the GUI 120, the design object 144 for modification or use, such as incorporating the design object 144 into the larger overall 3D design displayed in the GUI 120.

The GUI 120 can be any type of user interface that allows users to interact with one or more software applications via any number and/or types of GUI elements. The GUI 120 can be displayed in any technically feasible fashion on any number and/or types of stand-alone display device, any number and/or types of display screens that are integrated into any number and/or types of user devices, or any combination thereof. The design exploration application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. Some examples of types of interactive GUI elements include, without limitation, scroll bars, buttons, text entry boxes, drop-down lists, and sliders. In some embodiments, the design exploration application 130 organizes GUI elements into one or more container GUI elements (e.g., panels and/or panes).

The local data store 140 is a part of storage in the client device 110 that stores one or more design objects 144 included in an overall 3D design and/or one or more data files 142 associated with the overall 3D design. For example, an overall 3D design for a building can include multiple stored design objects 144, including design objects 144 separately representing doors, windows, fixtures, walls, appliances, and so forth. The local data store 140 can also include data files 142 relating to an overall 3D design (e.g., component files, metadata, etc.). Additionally or alternatively, the local data store 140 includes data files 142 related to generating prompts for transmission to the one or more ML models 180, 190. For example, the local data store 140 can store one or more data files 142 for sketches, geometries (e.g., wireframes, meshes, etc.), images, videos, application states (e.g., camera angles used within a design space, tools selected by a user, etc.), audio recordings, and so forth.

The design objects 144 include geometries, textures, images, and/or other components that the design exploration application 130 uses to generate an overall 2D or 3D design. In some embodiments, the geometry of a given design object refers to any multi-dimensional model of a physical structure, including CAD models, meshes, and point clouds, as well as building layouts, circuit layouts, piping diagrams, free-body diagrams, and so forth. In some embodiments, the design exploration application 130 stores multiple design objects 144 for a given overall 3D design and stores multiple iterations of a given target object that the ML models 180, 190 have iteratively modified. For example, the user can form and input a first prompt using the design exploration application 130 and receive a first generated design object 144 from the trained ML model 180 as an ML response to the first prompt, then submit a second prompt (e.g., by refining the first prompt) and receive a second generated design object 144 from the trained ML model 180 as an ML response to the second prompt.

The network 150 can be any technically feasible set of interconnected communication links, including a local area network (LAN), wide area network (WAN), the World Wide Web, or the Internet, among others. The network 150 enables communications between the client device 110 and other devices in network 150 via wired and/or wireless communications protocols, including Bluetooth, Bluetooth low energy (BLE), wireless local area network (WiFi), cellular protocols, satellite networks, and/or near-field communications (NFC).

The server device 160 is configured to communicate with the design exploration application 130 to generate one or more ML responses (such as design objects) in response to one or more prompts. In operation, the server device 160 executes the intent management application 170 to process a received prompt generated by the design exploration application 130, select (based on the received prompt) one or more ML models 180, 190 trained to generate design objects 144 in response to the contents of the prompt, and input the prompt into the selected ML models 180, 190. Once the selected ML models 180, 190 generate the design objects 144 that are responsive to the prompt, the server device 160 transmits the generated design objects to the client device 110, where the generated design objects 144 are usable by the design exploration application 130. For example, the design exploration application 130 can display the generated design objects 144 in the GUI 120 for exploration, manipulation, and/or modification by the user.

In various embodiments, the processor 162 can be any instruction execution system, apparatus, or device capable of executing instructions. For example, the processor 162 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 162 is a programmable processor that executes program instructions to manipulate input data. In some embodiments, the processor 162 can include any number of processing cores, memories, and other modules for facilitating program execution.

The input/output (I/O) devices 164 include devices configured to receive input, including, for example, a keyboard, a mouse, and so forth. In some embodiments, the I/O devices 164 also includes devices configured to provide output, including, for example, a display device, a speaker, and so forth. Additionally or alternatively, the I/O devices 164 may further include devices configured to both receive and provide input and output, respectively, including, for example, a touchscreen, a universal serial bus (USB) port, and so forth.

The memory 166 includes a memory module, or collection of memory modules. In some embodiments, the memory 166 can include a variety of computer-readable media selected for their size, relative performance, or other capabilities: volatile and/or non-volatile media, removable and/or non-removable media, etc. The memory 166 can include cache, random access memory (RAM), storage, etc. The memory 166 can include one or more discrete memory modules, such as dynamic RAM (DRAM) dual inline memory modules (DIMMs). Of course, various memory chips, bandwidths, and form factors may alternately be selected. The memory 166 stores content, such as software applications and data, for use by the processor 162. In some embodiments, a storage (not shown) supplements or replaces the memory 166. The storage can include any number and type of external memories that are accessible to the processor 162 of the server device 160. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 166 generally stores one or more application programs including the intent management application 170 and the one or more trained ML models 180, and data (e.g., design history 182) for processing by the processor 112. In various embodiments, the memory 166 can include non-volatile memory, such as optical drives, magnetic drives, flash drives, or other storage. In some embodiments, separate data stores, such as one or more external data stores connected via the network 150 can supplement the memory 166. In various embodiments, the intent management application 170 and/or the one or more ML models 180 within the memory 166 can be executed by the processor 162 to implement the overall functionality of the server device 160 to coordinate the operation of the system 100 as a whole.

In various embodiments, the memory 166 can include one or more modules for performing various functions or techniques described herein. In some embodiments, one or more of the modules and/or applications included in the memory 166 may be implemented locally on the client device 110, server device 160, and/or may be implemented via a cloud-based architecture. For example, any of the modules and/or applications included in the memory 166 could be executed on a remote device (e.g., smartphone, a server system, a cloud computing platform, etc.) that communicates with the server device 160 via a network interface or an I/O devices interface. Additionally or alternatively, the intent management application 170 could be executed on the client device 110 and can communicate with the trained ML models 180 operating at the server device 160.

In various embodiments, the intent management application 170 receives a prompt from the design exploration application 130 and selects and inputs the prompt into an applicable ML model 180, 190. In some embodiments, one or more of the ML models 180, 190 are trained to respond to specific types of inputs, such as a ML model that is trained to generate design objects from a specific combination of modalities (e.g., text and images). In such instances, the intent management application 170 processes a prompt to determine the modalities of the data that are included and/or specified in the prompt and identifies one or more ML models 180, 190 that have been trained to respond to such a combination of modalities. Upon identifying the one or more appropriate ML models, the intent management application 170 selects an ML model (e.g., the trained ML model 180) and inputs the prompt into the selected ML model 180.

The trained ML models 180 include one or more generative ML models that have been trained on a relatively large amount of existing data and optionally any number of results (e.g., design objects 144 and evaluations provided by the user) to perform any number and/or types of prediction tasks based on patterns detected in the existing data. In various embodiments, the remote ML models 190 are additional trained ML models that communicate with the server device 160 to receive prompts via the intent management application 170. In some embodiments, the trained ML model 180 is trained using various combinations of data from multiple modalities, such as textual data, image data, sound data, and so forth. For example, in some embodiments, the one or more trained ML models 180 can include a third-generation Generative Pre-Trained Transformer (GPT-3) model, a specialized version of a GPT-3 model referred to as a “DALL-E2” model, a fourth-generation Generative Pre-Trained Transformer (GPT-4) model, and so forth. In various embodiments, the trained ML models 180 can be trained to generate design objects from various combinations of modalities. Such combinations include text, a CAD object, a geometry, an image, a sketch, a video, an application state, an audio recording, etc.).

In some embodiments, the ML models 180, 190 can be retrained using evaluations provided by the user. In these embodiments, the user can submit a first prompt for a particular design object 144 via the design exploration application 130, which submits the first prompt to the intent management application 170, which in turn inputs the first prompt to a selected ML model, which generates a design object 144 in response to the first prompt. The generated design object 144 is then returned to the design exploration application 130, which displays the generated design object 144 in the GUI 120. The user can then enter a second prompt that includes an evaluation (feedback) of the response received for the first prompt (i.e., the generated design object 144), such as “the received object is correct,” or “the received object is incorrect.” The intent management application 170 can then store the first prompt, the generated design object 144, and the second prompt as additional training data for retraining the ML models 180, 190 at a later time for improving the accuracy of the ML models 180, 190. As discussed below, the additional training data for retraining can be stored in the design history 182.

The design history 182 includes data and metadata associated with the one or more trained ML models 180 and/or the one or more remote ML models 190 generating design objects 144 in response to prompts provided by the design exploration application 130. In some embodiments, the design history 182 includes successive iterations of design objects 144 that a single ML model 180 generates in response to a series of prompts. Additionally or alternatively, the design history 182 includes multiple design objects 144 that were generated by different ML models 180, 190 in response to the same prompt. In some embodiments, the design history 182 includes evaluation feedback provided by the user for a given design object 144. In such instances, the server device 160 can use the design history 182 as additional training data to retrain the one or more ML models 180. Additionally or alternatively, the design exploration application 130 can retrieve contents of the design history 182 and display the retrieved contents to the user via the GUI 120.

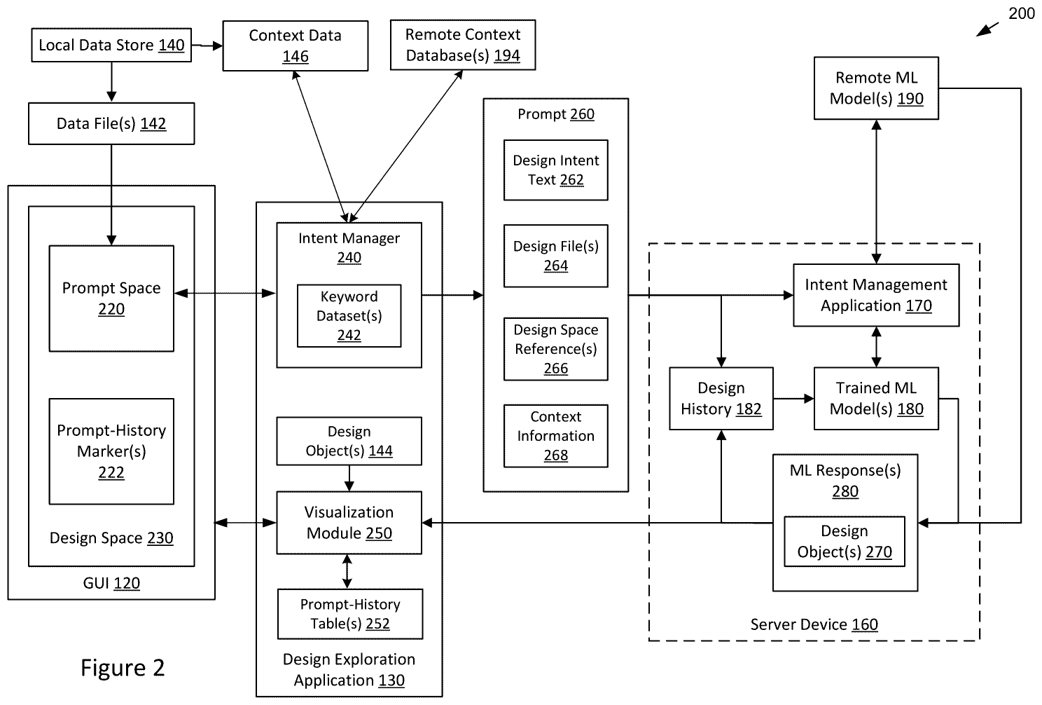

FIG. 2 is a more detailed illustration of the design exploration application 130 of FIG. 1, according to various embodiments. As shown, in some embodiments, the system 200 includes, without limitation, the design exploration application 130, the GUI 120, the local data store 140, the one or more data files 142, the context data 146, the one or more remote context databases 194, the server device 160, the remote ML models 190, and a prompt 260.

The GUI 120 includes, without limitation, a prompt space 220, zero or more prompt-history markers 222, and a design space 230. The design exploration application 130 includes, without limitation, an intent manager 240 including one or more keyword datasets 242, the one or more design objects 144, a visualization module 250, and one or more prompt-history tables 252. The server device 160 includes, without limitation, the intent management application 170, the one or more trained models 180, the design history 182, and one or more ML responses 280 (including one or more design objects 270) that are generated in response to received prompts 260. The prompt 260 includes, without limitation, a design intent text 262, one or more design files 264, one or more design space references 266, and/or context information 268.

For explanatory purposes only, the functionality of the design exploration application 130 is described herein in the context of exemplar interactive and linear workflows used to generate a generated design object 270 in accordance with user-based design-related intentions expressed during the workflow. The generated design object 270 includes, without limitation, one or more images, wireframe models, geometries, and/or meshes for use in a 2D or 3D design, as well and any amount (including none) and/or types of associated metadata.

As persons skilled in the art will recognize, the techniques described herein are illustrative rather than restrictive and can be altered and applied in other contexts without departing from the broader spirit and scope of the inventive concepts described herein. For example, the techniques described herein can be modified and applied to generate any number of generated design objects 270 associated with any target 3D object in a linear fashion, a nonlinear fashion, an iterative fashion, a non-iterative fashion, a recursive fashion, a non-recursive fashion, or any combination thereof during an overall process for generating and evaluating designs for that target 3D object. A target 3D object can include any number (including one) and/or types of target 3D objects and/or target 3D object components.

For example, in some embodiments, a generated design object 270 can be generated and displayed within the GUI 120 during a first iteration, any portion (including all) of the design object 270 can be selected via the GUI 120, and a first prompt 260 can be set equal to the selected portion of the generated design object 270 to recursively generate a second generated design object 270 during a second iteration. In the same or other embodiments, the design exploration application 130 can display and/or re-display any number of GUI elements, generate and/or regenerate any amount of data, or any combination thereof any number of times and/in any order while generating each new generated design object 270.

In operation, the visualization module 250 of the design exploration application 130 generates and renders the GUI 120, which includes the prompt space 220, zero or more prompt-history markers 222, and the design space 230. A user can provide at least a portion of the content for the prompt 260 via the prompt space 220 (by entering user inputs into the prompt space 220). The design exploration application 130 processes the content entered into the prompt space 220 to generate the prompt 260, adds optional additional information (such as context information 268), and transmits the prompt 260 to the server device 160. The intent management application 170 identifies the modalities of the data included in the prompt 260 and selects one or more trained ML models 180 and/or remote ML models 190 that have been trained to process the identified modalities. The intent management application 170 inputs the prompt into one or more of the selected ML models 180, 190. The ML models 180, 190 respond to the prompt 260 by generating one or more ML responses 280 that can include one or more design objects 270 along with additional information, such as one or more text responses. The visualization module 250 receives the one or more generated design objects 270 and displays the one or more generated design objects 270 in the prompt space 220 and/or the design space 230.

In various embodiments, the design space 230 is a virtual workspace that includes one or more renderings of design objects (e.g., geometries of the current design objects 144 and/or newly generated design objects 270) that form an overall 3D design. In some embodiments, the design space includes multiple design alternatives for the overall 3D design. For example, the design space 230 may graphically organize multiple 3D designs that include differing combinations of design objects 144, 270. In such instances, the design exploration application 130 provides various tools to enable the user to interact with the GUI 120 to explore the design space 230 and navigate between design alternatives to quickly analyze tradeoffs between different design options, observe trends in design options, constrain the design space, select specific design options, and so forth.

The prompt space 220 is panel in which a user can input content that is used to generate prompts 260. In various embodiments, the intent manager 240 determines the intent of inputs provided by the user. For example, the intent manager 240 can comprise a natural language (NL) processor that parses text provided by the user. Additionally or alternatively, the intent manager 240 can include processes audio data to identify words included in audio data and parse the identified words. In various embodiments, the intent manager 240 identifies one or more keywords in textual data. In some embodiments, the intent manager 240 includes one or more keyword datasets 242 that the intent manager 240 references when identifying the one or more keywords included in textual data.

For example, the keyword datasets 242 can include, without limitation, a 3D keyword dataset that includes any number and/or types of 3D keywords, a customized keyword dataset that includes any number and/or types of customized keywords, and/or a user keyword dataset that includes any number and/or types of user keywords (e.g., words and/or phrases specified by a user). The keywords can comprise particular words or phrases (e.g., demonstrative pronouns, technical terms, referential terms, etc.) that are relevant to designing 3D objects. For example, a user can input a regular sentence (“I want a hinge to connect here”) within an input area within the prompt space 220. The intent manager identifies “hinge,” “connect,” and “here” as words relevant to the ML model 180, 190 generating a design object 270. In such instances, the intent manager 240 can update the prompt space 220 by highlighting the keywords, enabling the user to provide additional details (e.g., non-textual data) for inclusion in the prompt 260.

The design exploration application 130 receives textual and/or non-textual data to include in the prompt 260 via the input area included in the prompt space 220. When providing non-textual data, the user can retrieve stored data, such as one or more stored data files 142 (e.g., stored geometries, stored CAD files, audio recordings, stored sketches, etc.) from the local data store 140. Additionally or alternatively, the user can retrieve contents from the design history 182 and can add the contents into the input area. In such instances, the contents from the design history 182 is stored in one or more data files 142 that the user retrieves from the local data store 140.

The prompt 260 is a prompt that specifies the design intent of the user. In various embodiments, the design exploration application 130 receives content/data and builds the prompt 260 based on the received content/data. For example, a user can initially write design intent text 262 that refers to a sketch. The design exploration application 130 then receives a sketch (e.g., a stored sketch or a sketch the user inputs into an input design area). Upon receiving the sketch, the design exploration application 130 can then generate the prompt 260 to include both the design intent text 262 and the sketch. The design intent text 262 includes textual data that describes the intent of the user. For example, the design intent text can include descriptions for characteristics of a target 3D design object (e.g., “a handle made of titanium”). In some embodiments, the design exploration application 130 generates design intent text from a different type of data input. For example, the intent manager 240 can perform NL processing to identify words included in an audio recording. In such instances, the design exploration application 130 generates design intent text 262 that includes the identified words.

The design files 264 includes one or more files (e.g., CAD files, stored text, audio recordings, stored geometries, etc.) that the user adds to be included in the prompt 260. In some embodiments, the design files 264 can include textual data (e.g., textual descriptions, physical dimensions, etc.). In some embodiments, the design exploration application 130 converts various types of data into the design files 264. For example, the user can record audio via the input area. In such instances, the design exploration application 130 can store audio recording as a design file 264. The design files 264 can include one or more modalities (e.g., textual data, video data, audio data, image data, etc.).

In some embodiments, the design space references 266 can include one or more references to the prompt space 220 and/or the design space 230. For example, the user can input text that references a specific application state (e.g., “make the thing selected by the current tool lighter,” “generate a seat for the car in this view,” etc.). In such instances, the design exploration application 130 determines the application state the user is referencing. The design exploration application 130 can then include the reference in the prompt 260 as the design space reference 266.

In various embodiments, the intent management application 170 receives and processes the prompt 260 to identify the modalities of the contents of the prompt 260. For example, the intent management application 170 processes the modalities of the design intent text 262, the one or more design files 264, and/or the one or more design space references 266 included in the prompt 260. For example, the intent management application 170 can identify a combination of text, image, and video modalities included in the prompt. The intent management application 170 identifies at least one ML model 180, 190 that was trained with that combination of modalities and selects one of the identified ML models 180, 190. The intent management application 170 executes the selected ML model by inputting the prompt 260 into the selected ML model. The selected ML model generates a design object 270 in response to the prompt 260. In some embodiments, the server device 160 includes the generated design object 270 in the design history 182. In such instances, the generated design object 270 is a portion of the design history 182 that can be used as additional training data to retrain one or more trained ML models 180 (e.g., further training the selected ML model, training other ML models, etc.).

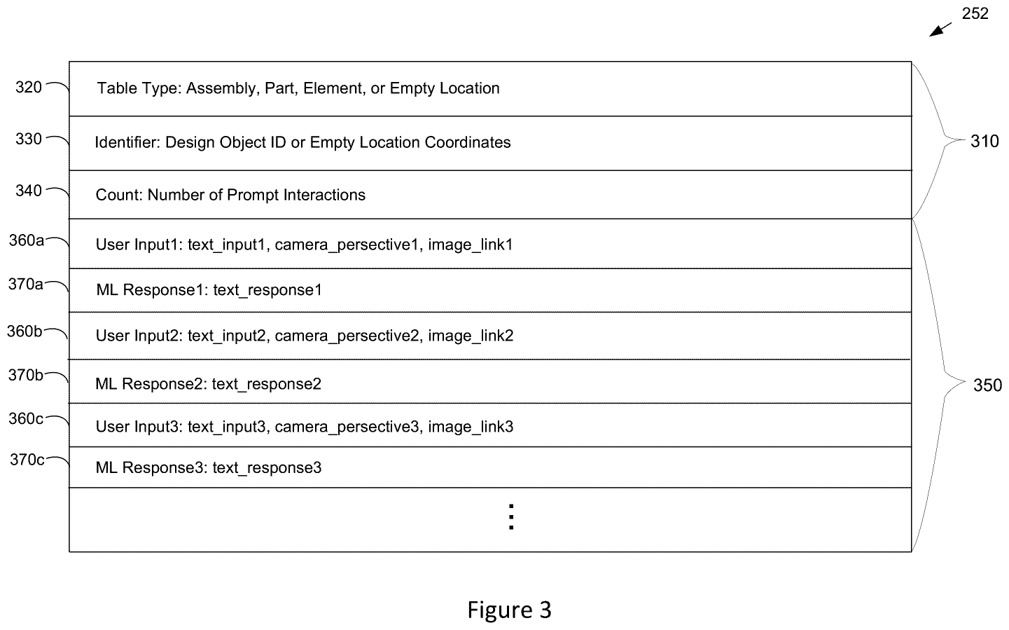

FIG. 3 is a conceptual diagram of one of the prompt-history tables 252 of FIG. 2, according to various embodiments. In some embodiments, the prompt-history table 252 comprises any type of data structure or data container for storing and organizing data. The design exploration application 130 can generate and store a prompt-history table 252 to memory 116 for a particular design object 144 or empty location upon first receiving a user input via the prompt space 220 for the particular design object 144 or empty location within the design space 230. Therefore, each prompt-history table 252 is generated to store a prompt history for an associated design object 144 or empty location within the design space 230. In some embodiments, each prompt-history table 252 is a separate and independent table that is associated with a different design object 144 or different empty location within the design space 230. In this manner, the design exploration application 130 can separately store and track multiple different prompt histories for multiple different design objects 144 and/or empty locations within the design space 230. Note that a prompt-history table 252 can be generated for an empty location/space (i.e., a location/space not having a design object 144) within the design space 230 when the user interacts with the empty location/space, for example, to generate a design object 144 at the empty location/space, but changes his/her mind and decides not to generate any design object 144 at the empty location/space. Such user interactions with the empty location/space can include user inputs and corresponding ML responses 280 in the prompt space 220 that are recorded to a prompt-history table 252 that is generated and associated with the empty location/space.

As shown, the prompt-history table 252 includes a first section 310 and a second section 350. The first section 310 stores data describing the prompt-history table 252 and the associated design object 144 or empty location within the design space 230. The second section 350 stores the prompt interactions received in the prompt space 220 for the associated design object 144 or empty location, including user inputs and corresponding ML responses 280.

As shown, the first section 310 includes a table type field 320, an identifier field 330, and a count field 340. The table type field 320 specifies a type of design item with which the prompt-history table 252 is associated, such as an assembly object, a part object, an element object, or an empty location. As discussed below, the table type field 320 can be used to identify which prompt-history tables 252 and associated design objects 1144 correspond to a current zoom level of the design space 230 for displaying only particular prompt-history markers 222 within the design space 230 based on the current zoom level. The identifier field 330 uniquely identifies the prompt-history table 252 and the design item associated with the prompt-history table 252. In these embodiments, the design exploration application 130 stores a unique identifier for each design object 144 within the design space 230. Thus, for a design item comprising a design object 144, the identifier field 330 can specify the unique identifier for the design object 144. For a design item comprising an empty location, the identifier field 330 can specify the unique xyz coordinates of the empty location within the design space 230. Note that when a plurality of prompt-history tables 252 are generated and stored, the identifier field 330 also uniquely identifies each prompt-history table 252 within the plurality of prompt-history tables 252. The count field 340 stores a value for the prompt interaction count comprising the total number of prompt interactions received in the prompt space 220 so far for the associated design object 144 or empty location. The prompt interaction count can be incremented for each user input or ML response 280 received in the prompt space 220.

As shown, the second section 350 includes a plurality of user-input entries 360 (such as 360a, 360b, etc.) and a plurality of ML-response entries 370 (such as 370a, 370b, etc.). Each user-input entry 360 stores data associated with a particular user input received in the prompt space 220 for the associated design object 144 or empty location. For example, a user-input entry 360 for a user input can include the user text input (for example, in natural language), a camera perspective (camera position and the camera direction) of the associated design object 144 recorded when the user input was received in the prompt space 220, and/or a link to a snapshot image captured for the associated design object 144 when the user input was received in the prompt space 220. Each ML-response entry 370 stores data associated with a particular ML response 280 received in the prompt space 220 for the associated design object 144 or empty location, such as a text response (for example, in natural language) to a prompt 260 generated for a corresponding user input.

### Overview of Embodiments

In operation, the visualization module 250 updates the prompt space 220 and/or the design space 230 based on inputs by the user and/or data (responses) received from the server device 160. To start, the visualization module 250 can initially display the design space 230 without displaying the prompt space 220 so the user can explore and navigate the design space 230 without visual clutter. For example, the user can move the cursor to select various design objects 144 and/or empty locations within the design space 230. If the user desires to generate a prompt 260 to receive design guidance or assistance from the ML models 180, 190, the user can then invoke the prompt space 220 via a predetermined hotkey input.

Typically, the prompt space 220 is a panel, such as a window, that is separate from the design space 230. In some embodiments, the prompt space 220 is a panel/window that is integrated within/inside the design space 230, whereby at least a portion of the prompt space 220 overlaps/overlays at least a portion of the design space 230. In response to the user invoking the prompt space 220, the visualization module 250 can spatially place/locate the prompt space 220 within the design space 230 in an advantageous manner that promotes and improves the user's focus on the currently selected location in the design space 230. As noted above, in conventional approaches, the prompt space 220 is displayed as a panel that is separate from and outside the design space 230 in a manner that distracts the user's focus on a currently selected location in the design space 230.

In some embodiments, the visualization module 250 displays the prompt space 220 at a location within the design space 230 that is based on a current location of the user-controlled cursor or a currently selected location within the design space 230. For example, the currently selected location can be on a design object 144 which selected the design object 144, whereby the visualization module 250 can display the prompt space 220 proximate/adjacent to the selected design object 144 within the design space 230. For example, the currently selected location can be an empty location within the design space 230, whereby the visualization module 250 can display the prompt space 220 proximate/adjacent to the selected empty location within the design space 230. The prompt space 220 is used to interact with the ML models 180, 190 by submitting prompts 260 and then displaying the ML model responses 280 to the prompts 260. The prompt space 220 includes an input area where the user can enter content/data (user input) that is included in the prompt 260. The prompt space 220 also includes a response area that displays the ML response 280 to the prompt 260. For example, the ML response 280 can include a design object 270 and/or a text response, whereby the received design object 270 can be displayed in the design space 203 and/or prompt space 220 and the received text response can be displayed in the prompt space 220. The prompt space 220 can be used to perform one or more iterations of (1) entering user inputs/submitting prompts 260 and (2) receiving ML responses 280. When the user no longer wishes to use the prompt space 220, the user can close the prompt space 220 via a predetermined hotkey, which causes the prompt space 220 to no longer be displayed in the design space 230 and/or GUI 120.

Note that after one or more iterations of (1) entering user inputs/submitting prompts 260 and (2) receiving ML responses 280, the prompt space 220 effectively displays a prompt history that includes all prompt interactions/messages within the prompt space 220 received for the selected design object 144 or selected empty location. The prompt interactions of a prompt history includes one or more entered user inputs associated with one or more prompts 260 and one or more corresponding ML responses 280 (such as one or more text responses) received for the one or more prompts 260. In some embodiments, a prompt history is associated with a particular design object 144 or a particular empty location within the design space 230. In these embodiments, the prompt history associated with a particular design object 144 or a particular empty location includes only those prompt interactions received for the particular design object 144 or particular empty location and does not include prompt interactions received for other design objects 144 or empty locations. The visualization module 250 stores and maintains one or more prompt histories associated with one or more design objects 144 and/or one or more empty locations within the design space 230 via the one or more prompt-history tables 252. For a plurality of prompt-history tables 252, each prompt-history table 252 is a separate and independent table that is associated with a different design object 144 or different empty location within the design space 230. In this manner, the visualization module 250 can separately store and track multiple different prompt histories for multiple different design objects 144 and/or empty locations within the design space 230.

In some embodiments, the visualization module 250 can also display zero or more prompt-history markers 222 within the design space 230. Each prompt-history marker 222 represents a particular prompt-history table 252 and prompt history associated with a particular design object 144 or empty location within the design space 230. The prompt-history marker 222 can also display a count value for a total number of prompt interactions included in the corresponding prompt history. The visualization module 250 can display the prompt-history marker 222 proximate/adjacent to the corresponding design object 144 or empty location within the design space 230 to indicate to the user that there exists a previous prompt history associated with the particular design object 144 or empty location that the user may wish to explore and review. The user can then select the prompt-history marker 222, and in response, the visualization module 250 retrieves the corresponding prompt-history table 252 and displays the corresponding prompt history associated with the particular design object 144 or empty location.

To display the prompt history, the visualization module 250 can open and display a prompt space 220 that is placed proximate to the associated design object 144 or empty location. In some embodiments, the visualization module 250 only displays the prompt history associated with the particular design object 144 or empty location and does not display a prompt history that is not associated with the particular design object 144 or empty location. Via the prompt space 220, the user can view the related prompt history and also enter new user inputs for generating new prompts 260, which are then added to the prompt history and prompt-history table 252 for the associated particular design object 144 or empty location.

In some embodiments, the design exploration application 130 provides a zoom tool that enables different zoom levels for viewing the design space 230. In addition, a design object 144 of a design space 230 can comprise an assembly, a part, or an element. In these embodiments, the visualization module 250 displays particular prompt-history markers 222 based on a current zoom level selected for viewing the design space 230, whereby only those prompt-history markers 222 appropriate for the current zoom level are displayed and those prompt-history markers 222 not appropriate for the current zoom level are not displayed. For example, if a first current zoom level comprises a low “zoom-out” level corresponding to an assembly-level zoom, the visualization module 250 displays only those prompt-history markers 222 associated with design objects 144 comprising assemblies and does not display prompt-history markers 222 associated with design objects 144 comprising parts or elements. For example, if a second current zoom level comprises a medium “zoom-neutral” level corresponding to a part-level zoom, the visualization module 250 displays only those prompt-history markers 222 associated with design objects 144 comprising parts and does not display prompt-history markers 222 associated with design objects 144 comprising assemblies or elements. For example, if a third current zoom level comprises a high “zoom-in” level corresponding to an element-level zoom, the visualization module 250 displays only those prompt-history markers 222 associated with design objects 144 comprising elements and does not display prompt-history markers 222 associated with design objects 144 comprising assemblies or parts.

In some embodiments, for each user input associated with a design object 144 that is entered into the prompt space 220, the visualization module 250 also captures a user/camera viewpoint of the design object 144 at the point in time that the user input is entered into the prompt space 220. The user/camera viewpoint is captured and then stored to the corresponding prompt-history table 252 representing the prompt history associated with the design object 144, whereby the captured viewpoint is also associated with the specific user input within the prompt history. Later, when the user is viewing the prompt history associated with the design object 144, the user can select the particular user input from the prompt history, and in response, the visualization module 250 can apply the captured viewpoint to the design object 144 within the design space 230. In this manner, the user can see the viewpoint of the design object 144 at the moment in time that the user entered the corresponding user input to give context and better understanding of the corresponding user input.

In some embodiments, for each user input that is entered into the prompt space 220 relating to a particular design object 144 or empty location within the design space 230, the intent manager 240 automatically retrieves additional context information 268 and includes the additional context information 268 in the prompt 260 generated for the user input. Additional context information 268 can be retrieved from context data 146 stored to the local data store 140. Context data 146 can include data that is collected and stored by the design exploration application 130 during execution of the design application for designing the design space 230. Additional context information 268 can be retrieved from the one or more remote context databases 194. For example, a remote context database 194 can comprise a database for a manufacturer of assemblies and/or parts that includes information for the assemblies and/or parts. The additional context information 268 can be included in the prompt 260 to provide contextual information for the user input to allow the ML models 180, 190 to provide more accurate and useful ML model responses 280 to the prompts 260.

### Placement of the Prompt Space within the Design Space

Initially, the design exploration application 130 generates the GUI 120 comprising the design space 230 comprising zero or more design objects 144. A design object 144 can comprise an assembly, a part, or an element. An assembly comprises a design object 144 that includes a plurality of connected but distinct parts, each part comprising a separate design object 144. A part comprises a design object 144 that includes a plurality of connected but distinct elements (such as edges and/or faces), each element comprising a separate design object 144. Therefore, an assembly object includes a plurality of sub-objects comprising part objects, and a part object includes a plurality of sub-objects comprising element objects. The design exploration application 130 provides various tools to select, manipulate, and modify an assembly object, a part object, or an element object. For example, the design exploration application 130 can provide an assembly selection tool, a part selection tool, and an element selection tool. As another example, the design exploration application 130 can provide zoom tools for viewing the design space 230 that enable zooming out to view and select an assembly, zooming into a view of an assembly to view and select a particular part of the assembly, and further zooming into a view of a part to view and select a particular element of the part. In the embodiments described below, various inventive functions and processes are performed on a design object 144 comprising a part object. However, in other embodiments, the various inventive functions and processes described below can similarly be performed on a design object 144 comprising an assembly object or an element object. In further embodiments, the various inventive functions and processes described below can also similarly be performed on a selected empty location within the design space 230.

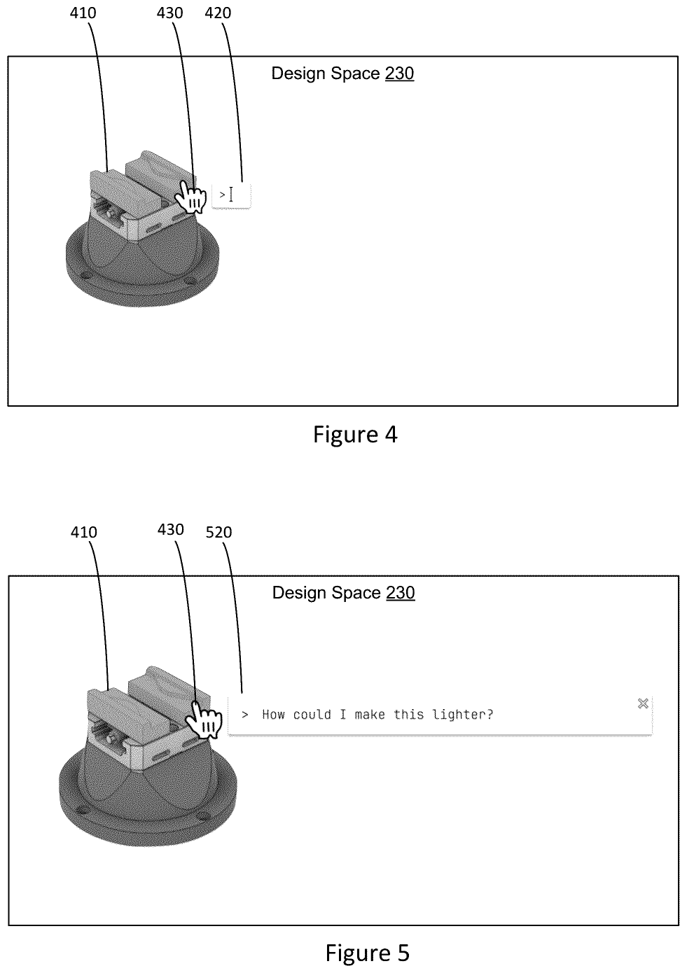

FIGS. 4-8 illustrate a prompt placement feature that places the prompt space 220 within the design space 230 based on user interactions within the design space 230. The prompt placement feature enables the user to invoke the prompt space 220 anywhere within the design space 230. In some embodiments, the various inventive functions and processes that enable the prompt placement feature are executed by the design exploration application 130 and the various modules of the design exploration application 130, as shown in FIG. 2.

FIG. 4 is an exemplar illustration of an initial selection of a design object 144 within the design space 230 of FIG. 2, according to various embodiments. As shown, the design space 230 includes a first design object 410 comprising a part object, whereby the user has moved the user-controlled cursor 430 to a particular location within the design space 230 to select the first design object 410. In response, the design exploration application 130 displays a collapsed prompt space 420 within the design space 230 that is placed proximate to the currently selected location and the currently selected first design object 410. The collapsed prompt space 420 displays a caret symbol to indicate that no previous prompt interactions have yet taken place for the selected first design object 410.

In general, a first GUI item can be placed “proximate” or “adjacent” to a second GUI item within the design space 230 using various techniques. In some embodiments, a prompt space 220 can be placed proximate to a currently selected location or currently selected design object 144 within the design space 230 using the various techniques. For example, the center point of the prompt space 220 can be placed within a predetermined distance from a currently selected location or design object 144 within the design space 230. Alternatively, the side of the prompt space 220 closest to the currently selected location or design object 144 within the design space 230 can be placed within a predetermined distance from the currently selected location or design object 144 within the design space 230. For example, the predetermined distance can be measured in terms of pixels or the native coordinate system of the design space 230. In other embodiments, other techniques are used to place the prompt space 220 proximate to a currently selected location or currently selected design object 144 within the design space 230. For example, another approach can place the prompt space 220 halfway between the currently selected location or design object 144 and the nearest edge of the screen, or to place prompt space 220 at a same point on the screen and include a “leader line” connecting the prompt space 220 to the currently selected location or design object 144. Similar techniques can be used, for example, to place a prompt-history marker 222 proximate to an associated design object 144 or empty location within the design space 230, or to place a snapshot image proximate to an associated user input within the prompt space 220.

FIG. 5 is an exemplar illustration of an interaction mode of the prompt space within the design space 230 of FIG. 4, according to various embodiments. Referring to FIG. 4, after selecting the first design object 410, the user can then start a new prompt interaction by invoking/activating an interaction mode of the prompt space. For example, the interaction mode of the prompt space can be invoked by selecting the collapsed prompt space 420, entering a predetermined hotkey combination, or entering a particular voice command. In some embodiments, while in interaction mode, the cursor cannot be moved and remains stationary at the current location within the design space 230 and can be moved once again when the interaction mode is disabled.

In response to activation of the interaction mode, the design exploration application 130 displays an expanded prompt space 520 within the design space 230 that is placed proximate to the currently selected location and the currently selected first design object 410. The expanded prompt space 520 includes an input area (indicated by the symbol “>”) where the user can enter text input that is used for generating a prompt 260 to be sent to an ML model 180, 190. As shown in the example of FIG. 5, the user enters a query “How could I make this lighter?” in reference to the currently selected first design object 410.

In some embodiments, upon receiving a first prompt interaction for a selected design object 144 or empty location within the design space 230, the design exploration application 130 generates and stores a new prompt-history table 252 associated with the selected design object 144 or empty location. As discussed above in relation to FIG. 3, the design exploration application 130 captures and stores various information in the prompt-history table 252 to record a prompt history associated with the selected design object 144 or empty location. For example, for each user input associated with a selected design object 144, the design exploration application 130 can capture a camera viewpoint of the selected design object 144 at the point in time the user input was entered into the prompt space 220. The user can then later review the prompt history for a particular design object 144 or empty location, as discussed below.

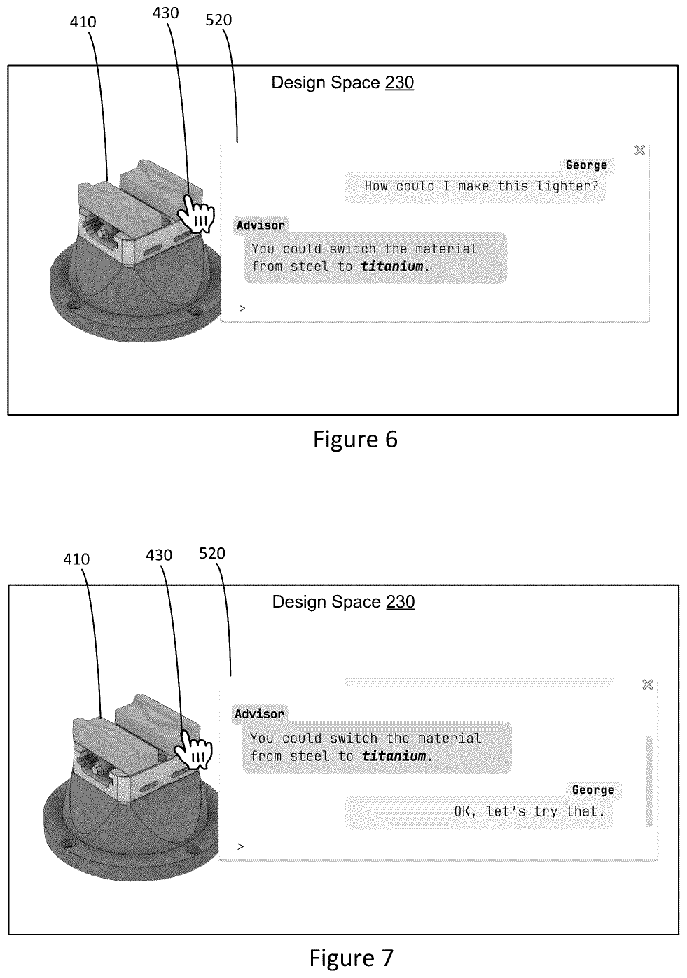

FIG. 6 is an exemplar illustration of an ML response 280 shown in the prompt space of FIG. 5, according to various embodiments. Referring to FIG. 5, the user enters the user input into the prompt space 520, and in response, the design exploration application 130 generates a prompt 260 based on the user input and transmits the prompt 260 to the server 160. In addition to the user input, the design exploration application 130 can include further data in the generated prompt 260, such as design intent text 262, one or more design files 264, one or more design space references 266, and/or context information 268. In particular, the design exploration application 130 can include geometry for the selected first design object 410 in the generated prompt 260 as the user is querying “How could I make this lighter?” in reference to the selected first design object 410. The server 160 (referred to as “Advisor”) implements an ML model 180, 190 and returns an ML response 280 for the prompt 260. As shown in the example of FIG. 6, the ML response 280 from the “Advisor” comprises a natural language text response (“You could switch the material from steel to titanium.”) to the user input query.

FIG. 7 is an exemplar illustration of an additional user input shown in the prompt space of FIG. 5, according to various embodiments. Referring to FIG. 6, the ML response 280 advises the user to switch the material of the selected first design object 410 from steel to titanium. In response, the user confirms that the suggested material change to titanium is to be made by entering the text “OK, let's try that” in the input area of the prompt space 520. Note that as further prompt interactions (user inputs and ML responses 280) are received for the selected first design object 410, the prompt space 520 automatically scrolls to the last prompt interaction, but the user can scroll upwards to view previous prompt interactions.

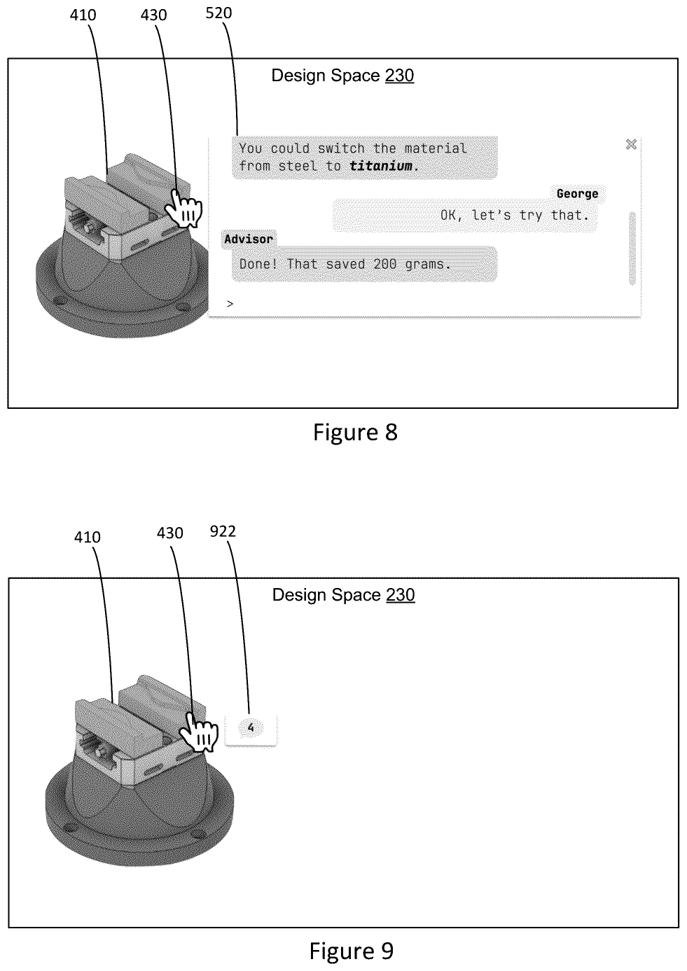

FIG. 8 is an exemplar illustration of an additional ML response shown in the prompt space of FIG. 5, according to various embodiments. Referring to FIG. 7, in response to the user input confirming the material change to titanium, the design exploration application 130 generates an additional prompt 260 based on the user input and transmits the additional prompt 260 to the server 160. The server 160 implements an ML model 180, 190 and returns an additional ML response 280 for the additional prompt 260. As shown in the example of FIG. 7, the additional ML response 280 from the “Advisor” includes a natural language text response (“Done! That saved 200 grams”) to the user input. Note that the additional ML response 280 would also include a modified first design object 410 that is automatically included and displayed in the design space 230.

In some embodiments, for each user input that is entered into the prompt space 220 relating to a selected design object 144 or empty location within the design space 230, the intent manager 240 automatically retrieves additional context information 268 and includes the additional context information 268 in the prompt 260 generated for the user input. For example, the additional context information 268 can include a snapshot image of the design object 144 that is captured for the user input, and/or geometry for the selected design object 144. The additional context information 268 can be included in the prompts 260 to provide contextual information for the user inputs, which advantageously allows the ML models 180, 190 to provide more accurate and useful ML model responses 280 to the prompts 260.

In some embodiments, the additional context information 268 can be retrieved from context data 146 stored to the local data store 140. Context data 146 can include data that is generated and stored by the design exploration application 130 during execution of the design application for designing and displaying the design space 230. For example, context data 146 can include recently executed design application commands (such as the last 10 most recent commands executed within the design space 230) or include recently executed design application commands associated with the selected design object 144 (such as the last 10 most recent commands executed on the selected design object 144). The context data 146 can further include, without limitation, a current state of the selected design object 144 and/or design space 230, geometry for one or more other design objects 144 connected to the selected design object 144, a current material associated with the selected design object 144, and the like. The context data 146 can further include, without limitation, context about the user who created the design object 144, such as design tools typically used, how long the user has been using the design application, the expertise level, etc.

In some embodiments, the additional context information 268 can be retrieved from the one or more remote context databases 194. For example, a remote context database 194 can comprise a database for a manufacturer of assemblies and/or parts that includes specification information for the assemblies and/or parts. In these embodiments, the additional context information 268 can include the manufacturer's specifications of the selected design object 144 (such as a selected assembly object or part object), such as manufacturer name, assembly/part name, model type, common or optional/possible physical dimensions (width, height, depth), common or optional/possible weights or mass, common or possible materials, common or optional/possible manufacturing processes used, environmental information (such as embodied carbon or embodied greenhouse gas emissions released during the life cycle), and the like.

### Displaying Prompt Histories within the Design Space

FIGS. 9-13 illustrate a prompt history feature that enables a user to view the prompt history associated with a particular design object 144 or empty location within the design space 230. In these embodiments, the design exploration application 130 displays zero or more prompt-history markers 222 within the design space 230. Each prompt-history marker 222 represents a particular prompt-history table 252 and prompt history associated with a particular design object 144 or empty location within the design space 230. The design exploration application 130 can display the prompt-history marker 222 proximate/adjacent to the corresponding design object 144 or empty location within the design space 230. The user can then select the prompt-history marker 222, and in response, the design exploration application 130 retrieves the corresponding prompt-history table 252 and displays the corresponding prompt history associated with the particular design object 144 or empty location. In some embodiments, the various inventive functions and processes that enable the prompt history feature are executed by the design exploration application 130 and the various modules of the design exploration application 130, as shown in FIG. 2.

FIG. 9 is an exemplar illustration of a prompt-history marker displayed within the design space of FIG. 4, according to various embodiments. Referring to FIG. 8, after receiving the additional ML response 280, the user wishes to exit/disable the interactive mode of the prompt space 520 and close the prompt space 520. For example, the interaction mode of the prompt space 520 can be disabled and the prompt space 520 closed by selecting the “X” icon in upper corner of the prompt space 520, entering a particular hotkey (predetermined key combination), or entering a predetermined voice command. In response to the interaction mode being disabled, the design exploration application 130 closes the prompt space 520 and displays a first prompt-history marker 922 proximate to the first design object 410 within the design space 230. In general, a prompt-history marker 922 can be placed proximate to a currently selected location or currently selected design object 144 within the design space 230 using similar techniques as for placing a prompt space 220 proximate to a currently selected location or currently selected design object 144 within the design space 230 discussed above.

The first prompt-history marker 922 indicates that there exists a first prompt history associated with the first design object 410 that the user may wish to review and explore. The first prompt history associated with the first design object 410 is stored and tracked in a corresponding first prompt-history table 252 that was generated for the first design object 410. The first prompt-history marker 922 can also display a count value for a total number of prompt interactions included in the first prompt history. In the example of FIG. 9, the first prompt-history marker 922 display a count value of “4” since there are a total of 4 prompt interactions included in the first prompt history.

The design exploration application 130 continues to display the first prompt-history marker 910 as the user explores and modifies the design space 230. Then at any later time, the user can select the first prompt-history marker 910 to view the first prompt history associated with the first design object 410. In other embodiments, the user can view the first prompt history by selecting the first design object 410 and then enter the particular hotkey for invoking a prompt space. In response to the user selecting to view the first prompt history, the design exploration application 130 retrieves and uses the corresponding first prompt-history table 252 to display the corresponding first prompt history associated with the first design object 410, which is illustrated in FIG. 8. As shown in FIG. 8, to display the first prompt history, the design exploration application 130 can open and display a prompt space 520 that is placed proximate to the first design object 410 and display the prompt interactions of the first prompt history. Via the prompt space 520, the user can view the first prompt history and also enter new user inputs for generating new prompts 260, which are then added to the first prompt history and the first prompt-history table 252 for the first design object 410.

The design exploration application 130 can display a plurality of prompt-history markers 222 for a plurality of different design objects 144 or empty locations within the design space 230 with which the user has interacted. For example, the design exploration application 130 can display a plurality of prompt-history markers 222 within the design space 230 if no design object 144 or empty location is currently selected and the user enters a predetermined hotkey combination, which triggers the display of the plurality of prompt-history markers 222 within the design space 230.

However, if an overly large number of prompt-history markers 222 are displayed in the design space 230, the prompt-history markers 222 can become distracting to the user. To reduce such visual clutter, the design exploration application 130 can display the prompt-history markers 222 based on a current zoom level associated with the design space 230. In these embodiments, the design exploration application 130 provides a zoom tool that enables different zoom levels for viewing the design space 230. The design exploration application 130 can display particular prompt-history markers 222 based on a current selected zoom level, whereby only those prompt-history markers 222 for design objects 144 associated with the current zoom level are displayed and those prompt-history markers 222 for design objects 144 not associated with the current zoom level are not displayed. In some embodiments, prompt-history markers 222 associated with empty locations are not affected by the current zoom level and continue to be displayed regardless of the current zoom level.

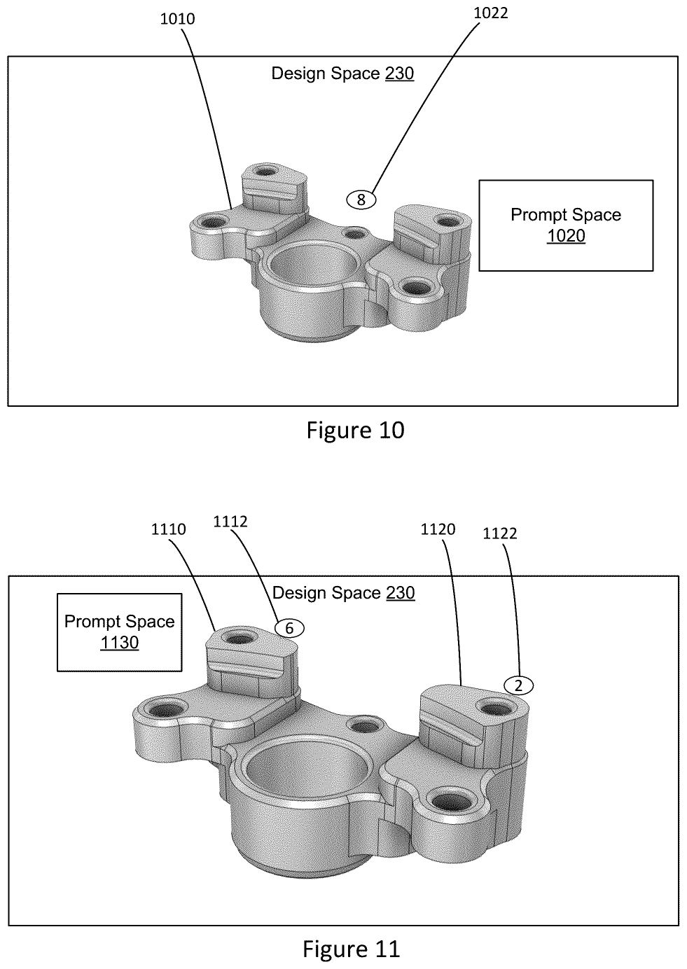

FIG. 10 is an exemplar illustration of an assembly-level prompt-history marker displayed within the design space 230 of FIG. 2, according to various embodiments. In the example of FIG. 10, a current zoom level comprises a first low “zoom-out” level corresponding to an assembly-level zoom for easily viewing assembly objects. As such, the first zoom level is associated with assembly objects and prompt-history markers 222 associated with assembly objects. As shown, the design exploration application 130 displays only those prompt-history markers 222 associated with design objects 144 comprising assemblies and does not display prompt-history markers 222 associated with design objects 144 comprising parts or elements. As shown, the design exploration application 130 displays a first prompt-history marker 1022 associated with a first assembly object 1010 within the design space 230. For example, the user can view the prompt history associated with the first assembly object 1010 by selecting the first prompt-history marker 1022, wherein the prompt history is displayed in a prompt space 1020 that is opened and located proximate to the first assembly object 1010.

FIG. 11 is an exemplar illustration of a set of part-level prompt-history markers displayed within the design space of FIG. 10, according to various embodiments. In the example of FIG. 11, the zoom level has increased from FIG. 10 to a current zoom level comprising a second medium “zoom-neutral” level corresponding to a part-level zoom for easily viewing part objects. As such, the second zoom level is associated with part objects and prompt-history markers 222 associated with part objects. As shown, the design exploration application 130 displays only those prompt-history markers 222 associated with design objects 144 comprising parts and does not display prompt-history markers 222 associated with design objects 144 comprising assemblies or elements. As shown, the design exploration application 130 displays a first prompt-history marker 1112 associated with a first part object 1110 and a second prompt-history marker 1122 associated with a second part object 1120 within the design space 230. For example, the user can view the prompt history associated with the first part object 1110 by selecting the first prompt-history marker 1112, wherein the prompt history is displayed in a prompt space 1130 that is opened and located proximate to the first part object 1110.

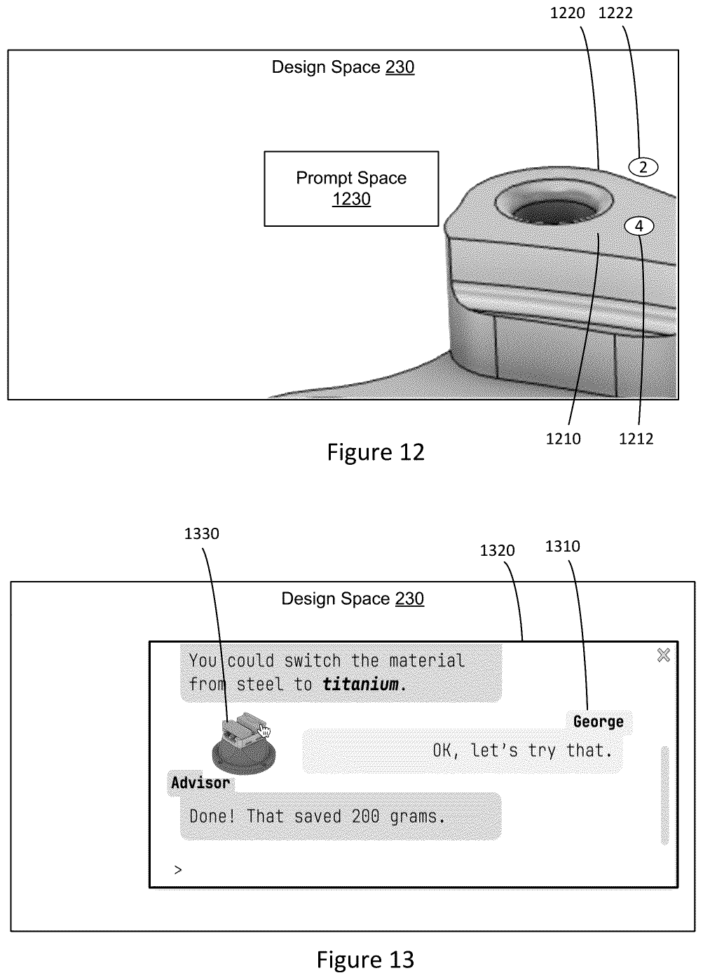

FIG. 12 is an exemplar illustration of a set of element-level prompt-history markers displayed within the design space of FIG. 10, according to various embodiments. In the example of FIG. 12, the zoom level has increased from FIG. 11 to a current zoom level comprising a third high “zoom-in” level corresponding to an element-level zoom for easily viewing element objects. As such, the third zoom level is associated with element objects and prompt-history markers 222 associated with element objects. As shown, the design exploration application 130 displays only those prompt-history markers 222 associated with design objects 144 comprising elements and does not display prompt-history markers 222 associated with design objects 144 comprising assemblies or parts. As shown, the design exploration application 130 displays a first prompt-history marker 1212 associated with a first element object 1210 (a surface element of a part) and a second prompt-history marker 1222 associated with a second element object 1220 (an edge element of a part) within the design space 230. For example, the user can view the prompt history associated with the first element object 1210 by selecting the first prompt-history marker 1212, wherein the prompt history is displayed in a prompt space 1230 that is opened and located proximate to the first element object 1210.

In some embodiments, for each user input associated with a design object 144 that is entered into the prompt space 220, the design exploration application 130 also captures a user viewpoint of the design object 144 at the point in time that the user input is entered into the prompt space 220. The user viewpoint is captured and then stored to the corresponding prompt-history table 252 representing the prompt history associated with the design object 144, whereby the captured viewpoint is also associated with the specific user input within the prompt history. The user viewpoint comprises a camera viewpoint of the design object 144 when the user input is entered. As discussed above in relation to FIG. 3, the camera viewpoint can be captured by recording the camera perspective including the camera position (in terms of xyz coordinates) and the camera direction (in terms of a vector) at the time the user input is entered.

In some embodiments, when the user later selects a prompt-history marker 222 representing a prompt history and a prompt-history table 252 for a particular design object 144, the design exploration application 130 opens a prompt space 222 that displays the prompt history for the particular design object 144, the prompt history comprising one or more user inputs. When the prompt history is initially displayed in the prompt space 222, the design exploration application 130 can automatically scroll to the last user input in the prompt history and recreate the user viewpoint of the particular design object 144 when the last user input was entered. The user viewpoint for the last user input can be recreated by applying the camera perspective (camera position and camera direction) captured for the last user input to the particular design object 144 within the design space 230. In this manner, an initial user viewpoint of the particular design object 144 displayed in the design space 230 is changed to display a captured user viewpoint of the particular design object 144 when the last user input was entered, which advantageously gives context and better understanding of the last user input. When the user closes the prompt space 220 displaying the prompt history, the design exploration application 130 then changes the user viewpoint of the particular design object 144 back to the initial user viewpoint.

In other embodiments, the user can select a specific user input from the prompt history, and in response, the design exploration application 130 can similarly apply the user viewpoint (camera perspective) captured for the selected user input to the design object 144 within the design space 230. In this manner, an initial user viewpoint of the particular design object 144 displayed in the design space 230 is changed to display a captured user viewpoint of the particular design object 144 when the selected user input was entered, which advantageously gives context and better understanding of the selected user input. When the user closes the prompt space 220 displaying the prompt history, the design exploration application 130 then changes the user viewpoint of the particular design object 144 back to the initial user viewpoint.

In alternative embodiments, the user viewpoint for a user input for a design object 144 can be captured via a snapshot image of the design object 144. As discussed above in relation to FIG. 3, a link to the snapshot image can be stored and associated with the user input in the prompt-history table 252 for the design object 144. In these embodiments, when the user views the prompt history for the design object 144 displayed in the prompt space 220, the user can select a particular user input. In response, the design exploration application 130 can retrieve the image captured for the selected user input using the prompt-history table 252 and display the image proximate to the selected user input in the prompt space 220. In some embodiments, the user selects the particular user input by hovering the cursor over the particular user input. In this manner, the user can quickly view images of the viewpoints associated with multiple user inputs in the prompt history by sequentially hovering over the multiple user inputs.

FIG. 13 is an exemplar illustration of a viewpoint image displayed in the prompt space of FIG. 2, according to various embodiments. As shown, a prompt history for a particular design object 144 is displayed in a prompt space 1320 displayed within the design space 230. The prompt history includes a plurality of prompt interactions, including a user input 1310 that is selected by the user (for example, by the cursor hovering over the user input 1310). In response to the selection of the user input 1310, the design exploration application 130 retrieves and displays a viewpoint image 1330 of the particular design object 144 that was captured when the selected user input 1310 was entered. The viewpoint image 1330 can be retrieved via a link stored to the prompt-history table 252 associated with the particular design object 144. As shown, the viewpoint image 1330 is displayed proximate to the selected user input 1310.

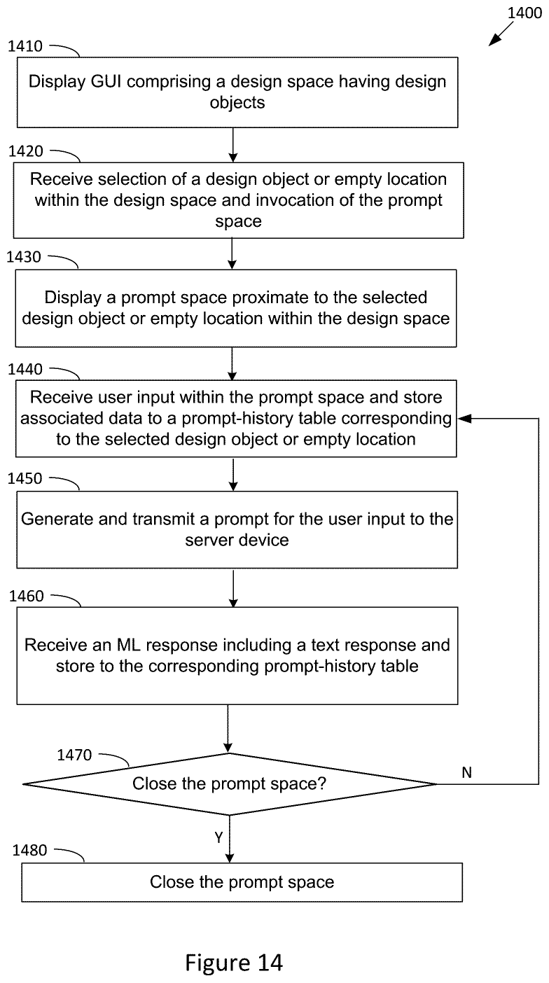

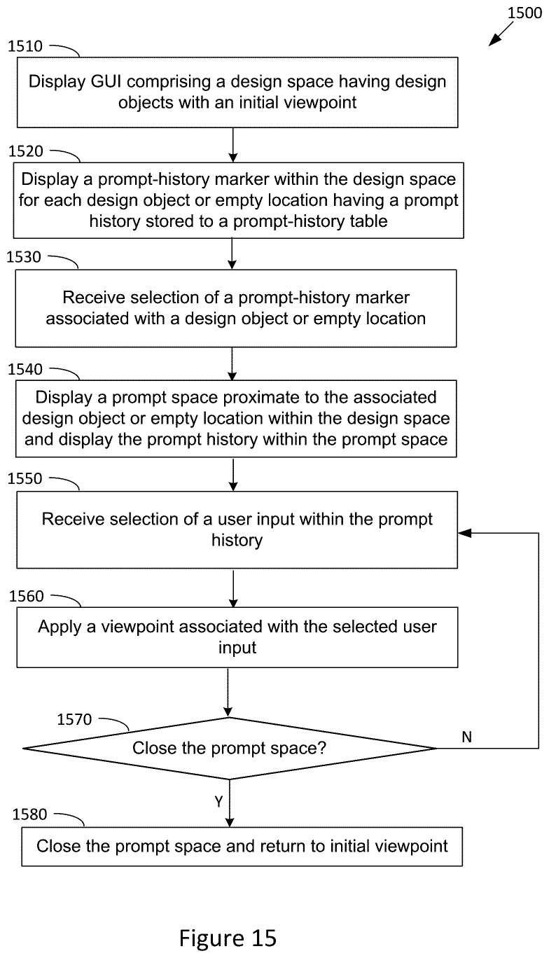

FIG. 14 sets forth a flow diagram of method steps for integrating a prompt space 220 within a design space 230, according to various embodiments. Although the method steps are described with reference to the systems of FIGS. 1-13, persons skilled in the art will understand that any system configured to implement the method steps, in any order, falls within the scope of the embodiments. In some embodiments, a prompt placement method 1400 is executed by the design exploration application 130 and the various modules of the design exploration application 130 to enable a prompt placement feature within the design space 230. In some embodiments, the method 1400 is executed in conjunction with a prompt history method 1500 described in relation to FIG. 15 which enables a prompt history feature within the design space 230.

As shown, the method 1400 begins at step 1410, where the design exploration application 130 displays a GUI 120 comprising a design space 230. The design space 230 displays one or more design objects 144. In some embodiments, the GUI 120 only displays the design space 230 and does not display the prompt space 220 as of yet. The design exploration application 130 then receives (at step 1420) a user selection of a location within the design space 230, such as a selection of a particular design object 144 or an empty location within the design space 230. The design exploration application 130 also receives a user invocation of the prompt space 220, such as the user entering a predetermined hotkey combination or a predetermined voice command which activates the invocation interaction mode of the prompt space 220.

In response to step 1420, the design exploration application 130 then opens and displays (at step 1430) a prompt space 220 at a placement location within the design space 230 that is based on the currently selected location within the design space 230, such as the location of the currently selected design object 144 or the currently selected empty location. In some embodiments, the prompt space 220 is a panel/window that is integrated within/inside the design space 230, whereby at least a portion of the prompt space 220 overlaps/overlays at least a portion of the design space 230. In some embodiments, the prompt space 220 is displayed proximate/adjacent to the currently selected design object 144 or the currently selected empty location within the design space 230.

The design exploration application 130 then receives (at step 1440) a user input (such as text input) within the prompt space 220 and stores data associated with the user input to a prompt-history table 252 corresponding to the currently selected design object 144 or empty location. If the user input is a first user input received for the currently selected design object 144 or empty location, the design exploration application 130 first generates the corresponding prompt-history table 252 and stores to the memory 116. The design exploration application 130 can further capture a snapshot image of the currently selected design object 144 and store to the memory 116. The data captured for the user input can include the text input and viewpoint information (such as camera perspective information and/or a link to the snapshot image). The design exploration application 130 also increments the prompt interaction count stored in the corresponding prompt-history table 252.

The design exploration application 130 then generates and transmits (at step 1450) a prompt 260 for the user input to the server device 160. The prompt 260 can include the user input, the design intent text 262, one or more design files 264, one or more design space references 266, and/or context information 268 (such as context data 146 and data retrieved from one or more remote context databases 194). The design exploration application 130 then receives (at step 1460) an ML response 280 for the prompt 260 from the server device 160. The ML response 280. The ML response 280 includes a text response that is displayed in the prompt space 220 and is stored to the corresponding prompt-history table 252. The design exploration application 130 also increments the prompt interaction count stored in the corresponding prompt-history table 252. The ML response 280 can also include geometry for a new or modified design object 144, which is displayed in the design space 230.

The design exploration application 130 then determines (at step 1470) if a selection is received for closing the prompt space 220 (exiting the interaction mode of the prompt space 220), such as receiving a selection of the “X” icon in the prompt space 220, receiving a predetermined hotkey combination, or receiving a predetermined voice command. If a selection is not received for closing the prompt space 220 (at step 1470—No), the method 1400 continues at step 1440 to receive a new user input in the prompt space 220. If a selection is received for closing the prompt space 220 (at step 1470—Yes), the design exploration application 130 then closes (at step 1480) the prompt space 220. The method 1400 can then repeat at step 1410, or continue to step 1510 in the method 1500.

FIG. 15 sets forth a flow diagram of method steps for displaying a prompt history within a prompt space, according to various embodiments. Although the method steps are described with reference to the systems of FIGS. 1-13, persons skilled in the art will understand that any system configured to implement the method steps, in any order, falls within the scope of the embodiments. In some embodiments, a prompt history method 1500 is executed by the design exploration application 130 and the various modules of the design exploration application 130 to enable a prompt history feature within the design space 230. In some embodiments, the method 1500 is executed in conjunction with the prompt placement method 1400 described in relation to FIG. 14 which enables the prompt placement feature within the design space 230.

As shown, the method 1500 begins at step 1510, where the design exploration application 130 displays a GUI 120 comprising a design space 230. The design space 230 displays one or more design objects 144 with an initial viewpoint. In some embodiments, the GUI 120 only displays the design space 230 and does not display the prompt space 220 as of yet.

The design exploration application 130 also displays (at step 1520) a prompt-history marker 222 within the design space 230 for each design object 144 or empty location having an associated prompt history that is stored to a corresponding prompt-history table 252. Each prompt-history marker 222 is displayed proximate to the associated design object 144 or empty location within the design space 230 to indicate that a prompt history exists for the design object 144 or empty location. Each prompt-history marker 222 can display a count value for a total number of prompt interactions included in the corresponding prompt history. The design exploration application 130 can be activated to display the prompt-history markers 222, for example, in response to the user entering a predetermined hotkey combination, or entering a particular voice command.

In some embodiments, to reduce visual clutter, at step 1520 the design exploration application 130 displays only some prompt-history markers 222 based on a current zoom level associated with the design space 230, whereby only those prompt-history markers 222 associated with design objects 1440 associated with the current zoom level are displayed and those prompt-history markers 222 associated with design object 144 not associated with the current zoom level are not displayed. For example, the design exploration application 130 can determine that a current zoom level of the design space 230 corresponds to an assembly-level zoom, then identify only those prompt-history tables 252 associated with design objects 144 comprising assemblies, and only display prompt-history markers 222 for only those design objects 144. In some embodiments, prompt-history markers 222 associated with empty locations are not affected by the current zoom level and continue to be displayed regardless of the current zoom level.

The design exploration application 130 then receives (at step 1530) a user selection of a particular prompt-history marker 222 associated with a particular design object 144 or empty location within the design space 230. In response to step 1530, the design exploration application 130 then opens and displays (at step 1540) a prompt space 220 proximate to the associated design object 144 or empty location. The design exploration application 130 retrieves the prompt history stored to the prompt-history table 252 corresponding to the associated design object 144 or empty location and displays the prompt history in the prompt space 220. In some embodiments, only the prompt history for the associated design object 144 or empty location is displayed in the prompt space 220, whereby prompt histories of other design objects 144 or empty locations is not displayed in the prompt space 220. The prompt history can comprise one or more user inputs, including a last user input. In some embodiments, the design exploration application 130 also recreates a user viewpoint associated with the last user input by applying a camera perspective recorded for the last user input to the associated design object 144 for displaying the associated design object 144 with the recorded camera perspective within the design space 230.

The design exploration application 130 then receives (at step 1550) a user selection of a particular user input within the prompt history displayed in the prompt space 220. For example, the user selection can comprise a mouse click on the particular user input or hovering of the cursor over the particular user input. In response to step 1550, the design exploration application 130 then applies (at step 1560) a viewpoint associated with the selected user input. For example, if the user selection comprises a mouse click on the user input, the design exploration application 130 can apply a camera perspective recorded for the selected user input to the associated design object 144 for displaying the associated design object 144 with the recorded camera perspective within the design space 230. For example, if the user selection comprises hovering of the cursor over the user input, the design exploration application 130 can display a snapshot image captured for the associated design object 144 at the time the user input was entered. The snapshot image can be displayed within the prompt space 220 proximate to the selected user input.

The design exploration application 130 then determines (at step 1570) if a selection is received for closing the prompt space 220, such as receiving a selection of the “X” icon in the prompt space 220, receiving a predetermined hotkey combination, or receiving a predetermined voice command. If a selection is not received for closing the prompt space 220 (at step 1570—No), the method 1500 continues at step 1550 to receive a selection of another user input in the prompt space 220. If a selection is received for closing the prompt space 220 (at step 1570—Yes), the design exploration application 130 then closes (at step 1580) the prompt space 220 and returns to the initial viewpoint of the design space 230. The method 1500 can then repeat at step 1510, or continue to step 1410 in the method 1400.

### System Implementation

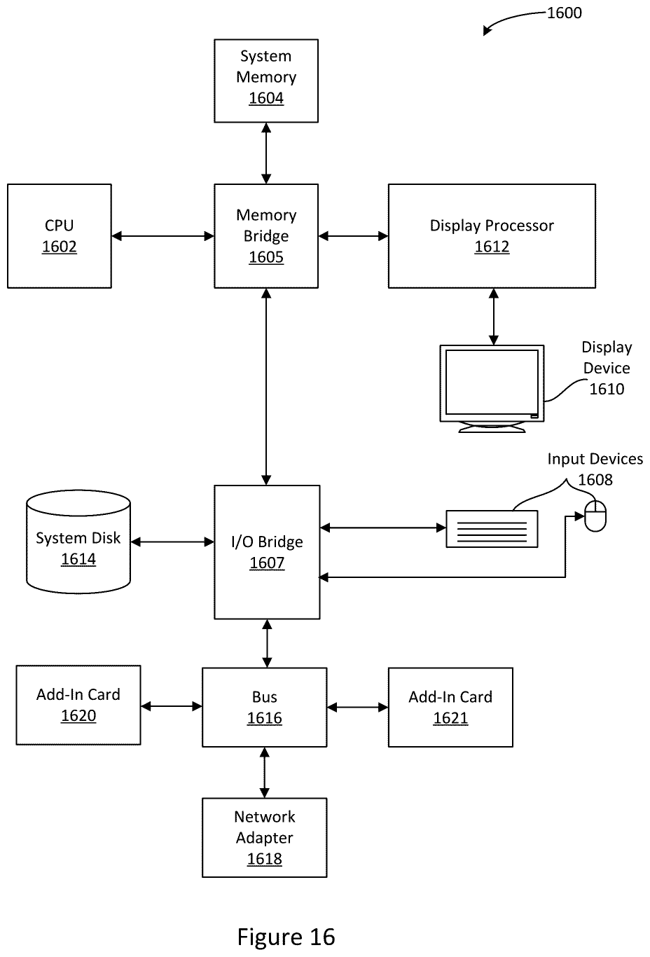

FIG. 16 depicts one architecture of a system within which the various embodiments may be implemented. In some embodiments, the client device 110 and the server device 160 of FIG. 1 can each be implemented as a system 1600 described herein. This figure in no way limits or is intended to limit the scope of the present disclosure. In various implementations, system 1600 may be an augmented reality, virtual reality, or mixed reality system or device, a personal computer, video game console, personal digital assistant, mobile phone, mobile device, or any other device suitable for practicing one or more embodiments of the present disclosure. Further, in various embodiments, any combination of two or more systems 1600 may be coupled together to practice one or more aspects of the present disclosure.

As shown, system 1600 includes a central processing unit (CPU) 1602 and a system memory 1604 communicating via a bus path that may include a memory bridge 1605. CPU 1602 includes one or more processing cores, and, in operation, CPU 1602 is the master processor of system 1600, controlling and coordinating operations of other system components. System memory 1604 stores software applications and data for use by CPU 1602. CPU 1602 runs software applications and optionally an operating system. Memory bridge 1605, which may be, e.g., a Northbridge chip, is connected via a bus or other communication path (e.g., a HyperTransport link) to an I/O (input/output) bridge 1607. I/O bridge 1607, which may be, e.g., a Southbridge chip, receives user input from one or more user input devices 1608 (e.g., keyboard, mouse, joystick, digitizer tablets, touch pads, touch screens, still or video cameras, motion sensors, and/or microphones) and forwards the input to CPU 1602 via memory bridge 1605.

A display processor 1612 is coupled to memory bridge 1605 via a bus or other communication path (e.g., a PCI Express, Accelerated Graphics Port, or HyperTransport link); in one embodiment display processor 1612 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 1604.

Display processor 1612 periodically delivers pixels to a display device 1610 (e.g., a screen or conventional CRT, plasma, OLED, SED or LCD based monitor or television). Additionally, display processor 1612 may output pixels to film recorders adapted to reproduce computer generated images on photographic film. Display processor 1612 can provide display device 1610 with an analog or digital signal. In various embodiments, one or more of the various graphical user interfaces set forth in Appendices A-J, attached hereto, are displayed to one or more users via display device 1610, and the one or more users can input data into and receive visual output from those various graphical user interfaces.

A system disk 1614 is also connected to I/O bridge 1607 and may be configured to store content and applications and data for use by CPU 1602 and display processor 1612. System disk 1614 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 1616 provides connections between I/O bridge 1607 and other components such as a network adapter 1618 and various add-in cards 1620 and 1621. Network adapter 1618 allows system 1600 to communicate with other systems via an electronic communications network, and may include wired or wireless communication over local area networks and wide area networks such as the Internet.

Other components (not shown), including USB or other port connections, film recording devices, and the like, may also be connected to I/O bridge 1607. For example, an audio processor may be used to generate analog or digital audio output from instructions and/or data provided by CPU 1602, system memory 1604, or system disk 1614. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 1612 incorporates circuitry optimized for graphics and video processing, including, for example, video output circuitry, and constitutes a graphics processing unit (GPU). In another embodiment, display processor 1612 incorporates circuitry optimized for general purpose processing. In yet another embodiment, display processor 1612 may be integrated with one or more other system elements, such as the memory bridge 1605, CPU 1602, and I/O bridge 1607 to form a system on chip (SoC). In still further embodiments, display processor 1612 is omitted and software executed by CPU 1602 performs the functions of display processor 1612.

Pixel data can be provided to display processor 1612 directly from CPU 1602. In some embodiments of the present disclosure, instructions and/or data representing a scene are provided to a render farm or a set of server computers, each similar to system 1600, via network adapter 1618 or system disk 1614. The render farm generates one or more rendered images of the scene using the provided instructions and/or data. These rendered images may be stored on computer-readable media in a digital format and optionally returned to system 1600 for display. Similarly, stereo image pairs processed by display processor 1612 may be output to other systems for display, stored in system disk 1614, or stored on computer-readable media in a digital format.

Alternatively, CPU 1602 provides display processor 1612 with data and/or instructions defining the desired output images, from which display processor 1612 generates the pixel data of one or more output images, including characterizing and/or adjusting the offset between stereo image pairs. The data and/or instructions defining the desired output images can be stored in system memory 1604 or graphics memory within display processor 1612. In an embodiment, display processor 1612 includes 3D rendering capabilities for generating pixel data for output images from instructions and data defining the geometry, lighting shading, texturing, motion, and/or camera parameters for a scene. Display processor 1612 can further include one or more programmable execution units capable of executing shader programs, tone mapping programs, and the like.

Further, in other embodiments, CPU 1602 or display processor 1612 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 1602, display processor 1612, or one or more other processing devices or any combination of these different processors.

CPU 1602, render farm, and/or display processor 1612 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 1600 may be a robot or robotic device and may include CPU 1602 and/or other processing units or devices and system memory 1604. In such embodiments, system 1600 may or may not include other elements shown in FIG. 1. System memory 1604 and/or other memory units or devices in system 1600 may include instructions that, when executed, cause the robot or robotic device represented by system 1600 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 1604 is connected to CPU 1602 directly rather than through a bridge, and other devices communicate with system memory 1604 via memory bridge 1605 and CPU 1602. In other alternative topologies display processor 1612 is connected to I/O bridge 1607 or directly to CPU 1602, rather than to memory bridge 1605. In still other embodiments, I/O bridge 1607 and memory bridge 1605 might be integrated into a single chip. The particular components shown herein are optional; for instance, any number of add-in cards or peripheral devices might be supported. In some embodiments, switch 1616 is eliminated, and network adapter 1618 and add-in cards 1620, 1621 connect directly to I/O bridge 1607.

In sum, the disclosed techniques can be used to generate 2D or 3D designs in a design space based on design intentions expressed by users via a prompt space in a GUI of a design exploration application 130. The prompt space enables a user to generate prompts for inputting to one or more ML models and receiving ML responses to the prompts. The design exploration application 130 initially displays the design space 230 without displaying the prompt space 220 so the user can explore and navigate the design space 230 without visual clutter. For example, the user can move the cursor to select various design objects 144 and/or empty locations without design objects 144 within the design space 230. If the user desires to generate a prompt 260 to receive design guidance or assistance from the ML models 180, 190, the user can then invoke the prompt space 220 anywhere in the design space 230. In response to the user invoking the prompt space 220, the design exploration application 130 can spatially place/locate the prompt space 220 within the design space 230.

In some embodiments, the prompt space 220 is a panel/window that is integrated within/inside the design space 230, whereby at least a portion of the prompt space 220 overlaps/overlays at least a portion of the design space 230. In some embodiments, the design exploration application 130 displays the prompt space 220 at a location within the design space 230 that is based on a current location of the user-controlled cursor. For example, the design exploration application 130 can display the prompt space 220 at a location within the design space 230 based on a location of a currently selected design object 144 within the design space 230 by placing the prompt space 220 proximate/adjacent to the currently selected design object 144 within the design space 230. For example, the design exploration application 130 can display the prompt space 220 at a location within the design space 230 based on a currently selected empty location (where there is no design object 144) within the design space 230 by placing the prompt space 220 proximate/adjacent to the currently selected empty location within the design space 230.

The prompt space 220 is used to interact with the ML models 180, 190 by submitting prompts 260 and then displaying the ML model responses 280 to the prompts 260. The prompt space 220 can be used to perform one or more iterations of (1) entering user inputs/submitting prompts 260 and (2) receiving ML responses 280. After one or more iterations of (1) entering user inputs/submitting prompts 260 and (2) receiving ML responses 280, the prompt space 220 effectively displays a prompt history that includes all prompt interactions within the prompt space 220 received for the selected design object 144 or selected empty location. The design exploration application 130 stores and maintains one or more prompt histories associated with one or more design objects 144 and/or one or more empty locations within the design space 230 via the one or more prompt-history tables 252. For a plurality of prompt-history tables 252, each prompt-history table 252 is a separate and independent table that is associated with a different design object 144 or different empty location within the design space 230. In this manner, the design exploration application 130 can separately store and track multiple different prompt histories for multiple different design objects 144 and/or empty locations within the design space 230.

In some embodiments, the design exploration application 130 displays zero or more prompt-history markers 222 within the design space 230. Each prompt-history marker 222 represents a particular prompt-history table 252 and prompt history associated with a particular design object 144 or empty location within the design space 230. The prompt-history marker 222 can also display a count value for a total number of prompt interactions included in the corresponding prompt history. The design exploration application 130 can display the prompt-history marker 222 proximate/adjacent to the corresponding design object 144 or empty location within the design space 230. The user can then select the prompt-history marker 222, and in response, the design exploration application 130 retrieves the corresponding prompt-history table 252 and displays the corresponding prompt history associated with the particular design object 144 or empty location. To display the prompt history, the design exploration application 130 can open and display a prompt space 220 that is placed proximate to the associated particular design object 144 or empty location.

In some embodiments, the design exploration application 130 displays particular prompt-history markers 222 based on a current zoom level selected for viewing the design space 230. In some embodiments, for each user input associated with a design object 144 that is entered into the prompt space 220, the design exploration application 130 also captures a viewpoint of the design object 144. Later, when the user selects the user input in a prompt history associated with the design object 144, the design exploration application 130 can apply the captured viewpoint to the design object 144 within the design space 230. In some embodiments, for each user input that is entered into the prompt space 220 relating to a particular design object 144 or empty location within the design space 230, the intent manager 240 also retrieves additional context information 268 and includes the additional context information 268 in the prompt 260 generated for the user input.

At least one technical advantage of the disclosed techniques relative to the prior art is that the disclosed techniques integrate the prompt space used to interact with an AI model within the design space of a CAD application, which can reduce the amount of distraction users experience when performing design operations in the design space. In this regard, with the disclosed techniques enable the prompt space to be displayed proximate to a currently selected location within the design space, such as a location associated with a currently selected 3D object or an empty location. Spatially placing the prompt space within the design space in association with the user's current focus reduces distraction from design work being performed in the design space and promotes a more efficient design process relative to what users experience with conventional implementations, where the prompt space is separatee from and external to the design space. These technical advantages provide one or more technological advancements over prior art approaches.

At least one technical advantage of the disclosed techniques relative to the prior art is that the disclosed techniques record separate and distinct prompt histories for separate and distinct 3D objects and empty locations within the design space. In this regard, in response to a user request to view the prompt history associated with a selected 3D object or empty location within the design space, the prompt history proximate to the selected 3D object or empty location is automatically displayed within the design space. Accordingly, with the disclosed techniques, only the prompt history associated with the selected 3D object or empty location is displayed proximate to the selected 3D object or empty location, which allows the user to more easily review and understand the prior design process and prompt interactions with the AI model relating to the selected 3D object or empty location, relative to conventional implementations. These technical advantages provide one or more technological advancements over prior art approaches.

Aspects of the subject matter described herein are set out in the following numbered clauses.

1. In some embodiments, a computer-implemented method for displaying a prompt space comprises displaying a design space comprising one or more design objects, receiving a selection of a current location within the design space, and displaying the prompt space at a placement location within the design space based on the current location.

2. The computer-implemented method of clause 1, further comprising receiving a first user input via the prompt space.

3. The computer-implemented method of clauses 1 or 2, further comprising generating a first prompt based on the first user input, and transmitting the first prompt to a trained machine learning (ML) model for processing.

4. The computer-implemented method of any of clauses 1-3, further comprising receiving a first ML response to the first prompt from the trained ML model, and displaying the first ML response within the prompt space.

5. The computer-implemented method of any of clauses 1-4, wherein the first user input is associated with a first design object within the design space, and further comprising generating a first prompt based on the first user input and context information associated with the first design object, and transmitting the first prompt to a trained machine learning (ML) model for processing.

6. The computer-implemented method of any of clauses 1-5, wherein the context information includes data generated by a design application that also generates the design space, wherein the data includes at least one of a set of executed design commands, a state of the first design object, a state of the design space, geometry for at least another design object that is coupled to the first design object, or a current material associated with the first design object.

7. The computer-implemented method of any of clauses 1-6, wherein receiving the selection of the current location comprises receiving a selection of a first design object within the design space.

8. The computer-implemented method of any of clauses 1-7, wherein displaying the prompt space at the placement location within the design space comprises displaying the prompt space proximate to the first design object.

9. The computer-implemented method of any of clauses 1-8, wherein receiving the selection of the current location comprises receiving a selection of an empty location within the design space.

10. The computer-implemented method of any of clauses 1-9, wherein displaying the prompt space at the placement location within the design space comprises displaying the prompt space proximate to the empty location.

11. In some embodiments, one or more non-transitory computer-readable media include instructions that, when executed by one or more processors, cause the one or more processors to display a prompt space by performing the steps of displaying a design space comprising one or more design objects, receiving a selection of a current location within the design space, and displaying the prompt space at a placement location within the design space based on the current location.

12. The one or more non-transitory computer-readable media of clause 11, further comprising receiving a first user input via the prompt space.

13. The one or more non-transitory computer-readable media of clauses 11 or 12, further comprising generating a first prompt based on the first user input, and transmitting the first prompt to a trained machine learning (ML) model for processing.

14. The one or more non-transitory computer-readable media of any of clauses 11-13, further comprising receiving a first ML response to the first prompt from the trained ML model, and displaying the first ML response within the prompt space.

15. The one or more non-transitory computer-readable media of any of clauses 11-14, wherein the first user input is associated with a first design object within the design space, and further comprising generating a first prompt based on the first user input and context information associated with the first design object, and transmitting the first prompt to a trained machine learning (ML) model for processing.

16. The one or more non-transitory computer-readable media of any of clauses 11-15, wherein the context information includes specification information retrieved from a manufacturer database for the first design object.

17. The one or more non-transitory computer-readable media of any of clauses 11-16, wherein the context information for the first design object includes at least one of a model type, possible physical dimensions, possible weights, possible materials, or possible manufacturing processes associated with the first design object.

18. The one or more non-transitory computer-readable media of any of clauses 11-17, wherein receiving the selection of the current location comprises receiving a selection of a first design object within the design space, the first design object comprising an assembly, a part, or an element.

19. The one or more non-transitory computer-readable media of any of clauses 11-18, wherein displaying the prompt space at the placement location within the design space comprises displaying the prompt space proximate to the first design object.

20. In some embodiments, a system comprises one or more memories storing instructions, and one or more processors coupled to the one or more memories that, when executing the instructions, perform the steps of displaying a design space comprising one or more design objects, receiving a selection of a current location within the design space, and displaying a prompt space at a placement location within the design space based on the current location.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments can be embodied as a system, method or computer program product. Accordingly, aspects of the present disclosure can take the form of an entirely hardware embodiment, an entirely software embodiment (including firmware, resident software, micro-code, etc.) or an embodiment combining software and hardware aspects that can all generally be referred to herein as a “module” or “system.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable medium(s) having computer readable program code embodied thereon. The software constructs and entities (e.g., engines, modules, GUIs, etc.) are, in various embodiments, stored in the memory/memories shown in the relevant system figure(s) and executed by the processor(s) shown in those same system figures.

Any combination of one or more non-transitory computer readable medium or media may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for displaying a prompt space, the method comprising:
displaying a design space comprising one or more design objects;
receiving a selection of a current location within the design space; and
displaying the prompt space at a placement location within the design space based on the current location.

2. The computer-implemented method of claim 1, further comprising receiving a first user input via the prompt space.

3. The computer-implemented method of claim 2, further comprising:
generating a first prompt based on the first user input; and
transmitting the first prompt to a trained machine learning (ML) model for processing.

4. The computer-implemented method of claim 3, further comprising:
receiving a first ML response to the first prompt from the trained ML model; and
displaying the first ML response within the prompt space.

5. The computer-implemented method of claim 2, wherein the first user input is associated with a first design object within the design space, and further comprising:
generating a first prompt based on the first user input and context information associated with the first design object; and
transmitting the first prompt to a trained machine learning (ML) model for processing.

6. The computer-implemented method of claim 5, wherein the context information includes data generated by a design application that also generates the design space, wherein the data includes at least one of a set of executed design commands, a state of the first design object, a state of the design space, geometry for at least another design object that is coupled to the first design object, or a current material associated with the first design object.

7. The computer-implemented method of claim 1, wherein receiving the selection of the current location comprises receiving a selection of a first design object within the design space.

8. The computer-implemented method of claim 7, wherein displaying the prompt space at the placement location within the design space comprises displaying the prompt space proximate to the first design object.

9. The computer-implemented method of claim 1, wherein receiving the selection of the current location comprises receiving a selection of an empty location within the design space.

10. The computer-implemented method of claim 9, wherein displaying the prompt space at the placement location within the design space comprises displaying the prompt space proximate to the empty location.

11. One or more non-transitory computer-readable media including instructions that, when executed by one or more processors, cause the one or more processors to display a prompt space by performing the steps of:
displaying a design space comprising one or more design objects;
receiving a selection of a current location within the design space; and
displaying the prompt space at a placement location within the design space based on the current location.

12. The one or more non-transitory computer-readable media of claim 11, further comprising receiving a first user input via the prompt space.

13. The one or more non-transitory computer-readable media of claim 12, further comprising:
generating a first prompt based on the first user input; and
transmitting the first prompt to a trained machine learning (ML) model for processing.

14. The one or more non-transitory computer-readable media of claim 13, further comprising:
receiving a first ML response to the first prompt from the trained ML model; and
displaying the first ML response within the prompt space.

15. The one or more non-transitory computer-readable media of claim 12, wherein the first user input is associated with a first design object within the design space, and further comprising:
generating a first prompt based on the first user input and context information associated with the first design object; and
transmitting the first prompt to a trained machine learning (ML) model for processing.

16. The one or more non-transitory computer-readable media of claim 15, wherein the context information includes specification information retrieved from a manufacturer database for the first design object.

17. The one or more non-transitory computer-readable media of claim 16, wherein the context information for the first design object includes at least one of a model type, possible physical dimensions, possible weights, possible materials, or possible manufacturing processes associated with the first design object.

18. The one or more non-transitory computer-readable media of claim 11, wherein receiving the selection of the current location comprises receiving a selection of a first design object within the design space, the first design object comprising an assembly, a part, or an element.

19. The one or more non-transitory computer-readable media of claim 18, wherein displaying the prompt space at the placement location within the design space comprises displaying the prompt space proximate to the first design object.

20. A system comprising:
one or more memories storing instructions; and
one or more processors coupled to the one or more memories that, when executing the instructions, perform the steps of:
displaying a design space comprising one or more design objects;
receiving a selection of a current location within the design space; and
displaying a prompt space at a placement location within the design space based on the current location.
